(19) United States
(12) Patent Application Publication
(10) Pub. No.: US 2025/0380542 A1
(43) Pub. Date: Dec. 11, 2025

(54) LIGHT-EMITTING MODULE

(71) Applicant: NICHIA CORPORATION, Anan-shi (JP)

(72) Inventor: Norimasa YOSHIDA, Komatsushima-shi (JP)

(73) Assignee: NICHIA CORPORATION, Anan-shi, Tokushima (JP)

(21) Appl. No.: 19/228,907

(22) Filed: Jun. 5, 2025

(30) Foreign Application Priority Data
Jun. 11, 2024 (JP) 2024-094629
Sep. 20, 2024 (JP) 2024-163968
Dec. 13, 2024 (JP) 2024-219366

(51) Int. Cl. H10H 20/855; H10H 20/856; H10H 20/857

(52) U.S. Cl. CPC H10H 20/855; H10H 20/856; H10H 20/857

(57) ABSTRACT

A light-emitting module includes: a light source; a first light-transmissive member including a first lens disposed above the light source; and a second light-transmissive member including a second lens disposed above the first light-transmissive member. The light source, the first lens, and the second lens are spaced apart from one another. A light incident surface of the second lens includes a first region overlapping an optical axis of the second lens and overlapping at least the light source, in a top view, and a second region surrounding the first region in the top view. The second lens includes, in the second region, at least one optical functional portion having a positive refractive power. The refractive power of the at least one optical functional portion is greater than a refractive power of the second lens in the first region.

### CROSS-REFERENCE TO RELATED APPLICATIONS

This application is based on and claims priority to Japanese Patent Application No. 2024-094629, filed on Jun. 11, 2024, Japanese Patent Application No. 2024-163968, filed on Sep. 20, 2024, and Japanese Patent Application No. 2024-219366, filed on Dec. 13, 2024. The entire contents of these applications are incorporated herein by reference.

### BACKGROUND

### 1. Technical Field

The present disclosure relates to a light-emitting module.

### 2. Description of Related Art

Light-emitting modules including semiconductor elements such as light-emitting diodes (LEDs) have been widely used. As such a light-emitting module, for example, Japanese Patent Publication No. 2003-515779 describes a device that concentrates or collimates radiant light emitted from a light source by using a lens having a structure with a discontinuous slope located outward of a light incident surface.

### SUMMARY

It is an object of one embodiment of the present disclosure to provide a light-emitting module having high light extraction efficiency.

A light-emitting module according to one embodiment of the present disclosure includes: a light source; a first light-transmissive member including a first lens disposed above the light source; and a second light-transmissive member including a second lens disposed above the first light-transmissive member.

The light source, the first lens, and the second lens are spaced apart from one another.

A light incident surface of the second lens includes a first region overlapping an optical axis of the second lens and overlapping at least the light source, in a top view, and a second region surrounding the first region in the top view.

The second lens includes, in the second region, at least one optical functional portion having a positive refractive power.

The refractive power of the at least one optical functional portion is greater than a refractive power of the second lens in the first region.

### BRIEF DESCRIPTION OF THE DRAWINGS

FIG. 1 is a schematic top view illustrating a light-emitting module according to a first embodiment;

FIG. 2 is a schematic cross-sectional view taken along line II-II of FIG. 1;

FIG. 3 is a schematic top view illustrating a configuration of a light source of the light-emitting module according to the first embodiment;

FIG. 4 is a schematic cross-sectional view taken along line IV-IV of FIG. 3;

FIG. 5A is an enlarged view of a VA region of FIG. 2;

FIG. 5B is an enlarged view of a VB region of FIG. 2;

FIG. 6 is a schematic top view of a light-emitting module according to a first modification;

FIG. 7 is a schematic cross-sectional view illustrating a surface interval between a first light-transmissive member and a second light-transmissive member of a light-emitting module according to a second modification;

FIG. 8A is a schematic cross-sectional view illustrating a surface interval between a first light-transmissive member and a second light-transmissive member of a light-emitting module according to Comparative Example 1;

FIG. 8B is a schematic cross-sectional view illustrating a surface interval between a first light-transmissive member and a second light-transmissive member of a light-emitting module according to Comparative Example 2;

FIG. 9 is a schematic top view illustrating a light-emitting module according to a second embodiment;

FIG. 10 is a schematic cross-sectional view taken along line X-X of FIG. 9;

FIG. 11A is an enlarged view illustrating a line connecting top portions in a region XI of FIG. 10 according to a first example;

FIG. 11B is an enlarged view illustrating a line connecting top portions in the region XI of FIG. 10 according to a second example;

FIG. 11C is an enlarged view illustrating a line connecting top portions in the region XI of FIG. 10 according to a third example;

FIG. 11D is an enlarged view illustrating a line connecting a plurality of top portions according to a fourth example;

FIG. 12 is a diagram illustrating the illuminance of irradiation light when one of light-emitting parts arranged at four corners of a light source is caused to emit light in the light-emitting module according to the second embodiment;

FIG. 13 is a diagram illustrating the illuminance of irradiation light when one of light-emitting parts arranged at four corners of a light source is caused to emit light in a light-emitting module according to Comparative Example 3;

FIG. 14 is a schematic cross-sectional view of a light-emitting module according to a third embodiment;

FIG. 15 is a diagram illustrating the illuminance of irradiation light when one of light-emitting parts arranged at four corners of a light source is caused to emit light in the light-emitting module according to the third embodiment;

FIG. 16 is a diagram illustrating the illuminance of irradiation light when one of light-emitting parts arranged at the four corners of the light source are caused to emit light in the light-emitting module according to the second embodiment;

FIG. 17 is a schematic top view illustrating a light-emitting module according to a fourth embodiment;

FIG. 18 is a schematic cross-sectional view taken along line XVIII-XVIII of FIG. 17;

FIG. 19 is a schematic cross-sectional view illustrating a light-emitting module according to a fifth embodiment;

FIG. 20 is a schematic top view illustrating a first light-transmissive member of the light-emitting module according to the fifth embodiment; and

FIG. 21 is a schematic cross-sectional view taken along line XXI-XXI of FIG. 20.

### DETAILED DESCRIPTION

Light-emitting modules according to embodiments of the present disclosure will be described in detail with reference to the accompanying drawings. The embodiments described below illustrate the light-emitting modules that embody technical ideas underlying the present invention, but the present invention is not limited to the described embodiments. In addition, unless otherwise specified, the dimensions, materials, shapes, relative arrangements, and the like of components described in the embodiments are not intended to limit the scope of the present invention thereto, but are described as examples. The sizes, positional relationships, and the like, of members illustrated in the drawings may be exaggerated for a better understanding of the structure. Further, in the following description, the same names and reference numerals refer to the same or similar members, and a detailed description thereof will be omitted as appropriate. An end view illustrating only a cut surface may be used as a cross-sectional view.

In the drawings, directions may be indicated by an X-axis, a Y-axis, and a Z-axis. The X-axis, the Y-axis, and the Z-axis are orthogonal to one another. An X direction along the X-axis and a Y direction along the Y-axis indicate directions along a light-emitting surface of a light-emitting part included in any of the light-emitting modules according to the embodiments. A Z direction along the Z axis indicates a direction orthogonal to the light-emitting surface. That is, the light-emitting surface of the light-emitting part is parallel to the XY plane, and the Z-axis is orthogonal to the XY plane.

A direction indicated by an arrow in the X direction is referred to as a +X side direction, and a direction opposite to the +X side is referred to as a −X side direction. A direction indicated by an arrow in the Y direction is referred to as a +Y side direction, and a direction opposite to the +Y side is referred to as a −Y side direction. A direction indicated by an arrow in the Z direction is referred to as a +Z side direction, and a direction opposite to the +Z side is referred to as a −Z side direction. The light-emitting part included in any of the light-emitting modules according to the embodiments to be described below is configured to emit light to the +Z side as an example. However, these expressions do not limit the orientations of the light-emitting modules during use, and the orientations of the light-emitting modules according to the embodiments are discretionary.

Further, in the present specification, a surface of the object as viewed from the +Z side is referred to as an “upper surface,” and a surface of the object as viewed from the −Z side is referred to as a “lower surface.” In the embodiments described below, each of “along the X-axis,” “along the Y-axis,” and “along the Z-axis” includes a case where the object is at an inclination within a range of ±10° with respect to the corresponding one of the axes. Further, in the embodiments, the term “orthogonal” may include a deviation within ±10° with respect to 90°.

Further, in the present specification and the claims, if there are multiple components and these components are to be distinguished from one another, the components may be distinguished by adding terms “first,” “second,” and the like before the names of the components. Further, objects to be distinguished may be different between the specification and the claims. Therefore, even if a component recited in the claims is denoted by the same reference numeral as that of a component described in the present specification, an object specified by the component recited in the claims is not necessarily identical with an object specified by the component described in the specification.

For example, if components are distinguished by the ordinal numbers “first,” “second,” and “third” in the specification, and components with “first” and “third” or components with “first” and without a specific ordinal number in the specification are described in the claims, these components may be distinguished by the ordinal numbers “first” and “second” in the claims for ease of understanding. In this case, the components with “first” and “second” in the claims respectively refer to the components with “first” and “third” or the components with “first” and without a specific ordinal number in the specification. This rule is applied not only to components but also other objects in a reasonable and flexible manner.

### First Embodiment

### <Example Configuration of Light-Emitting Module According to First Embodiment>

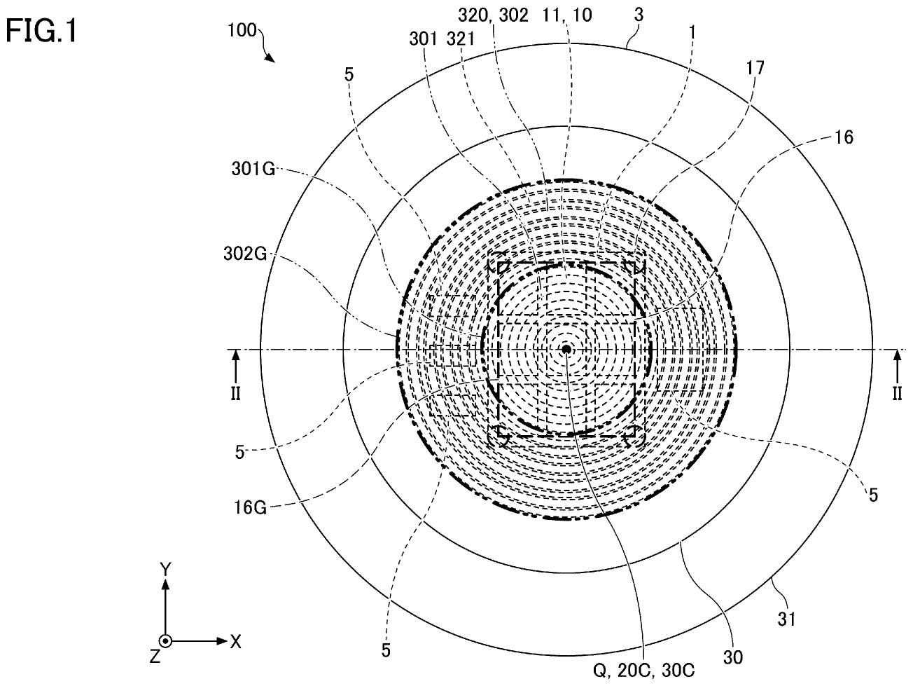

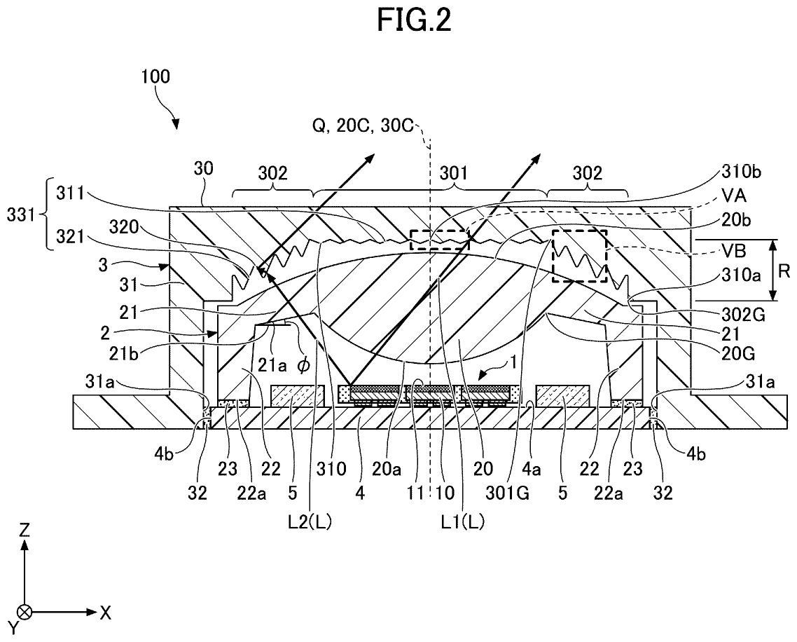

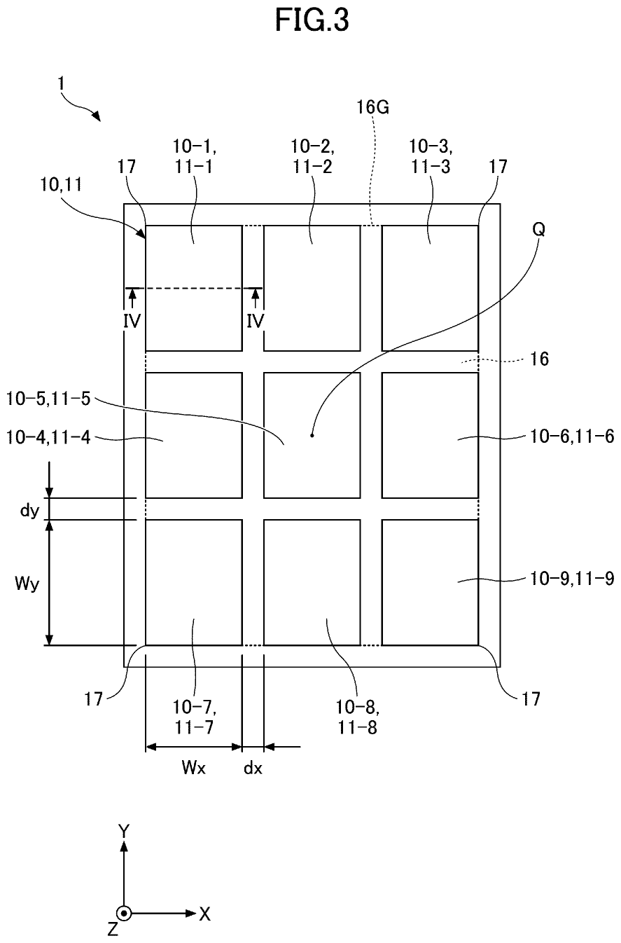

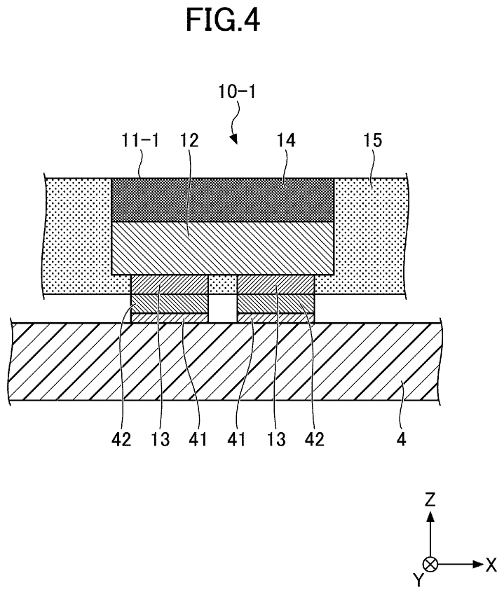

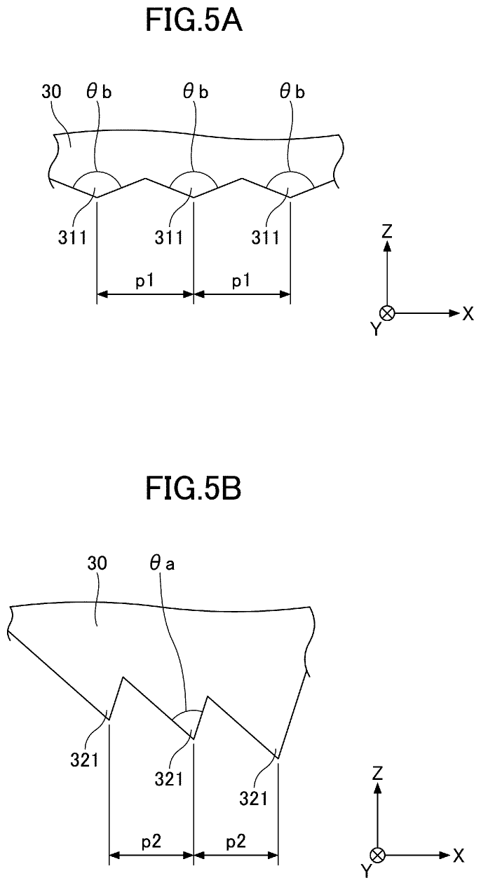

A configuration of a light-emitting module according to a first embodiment will be described with reference to FIG. 1 to FIG. 4, FIG. 5A, and FIG. 5B. FIG. 1 is a schematic top view illustrating an example of a light-emitting module 100 according to the first embodiment. FIG. 2 is a schematic cross-sectional view taken along line II-II of FIG. 1. FIG. 3 is a schematic top view illustrating a configuration of a light source 1 of the light-emitting module 100. FIG. 4 is a schematic cross-sectional view taken along line IV-IV of FIG. 3. FIG. 5A is an enlarged view of a VA region of FIG. 2. FIG. 5B is an enlarged view of a VB region of FIG. 2. In FIG. 1, there may be a case in which some components corresponding to those in the cross-sectional view of FIG. 2 are not illustrated in order to avoid excessive complication of the drawing. Further, in FIG. 2, each of light L1 and light L2 indicated by an arrow represents a portion of light L emitted from the light source 1 included in the light-emitting module 100.

As an example, the light-emitting module 100 is a light-emitting module used as a light source for a flash of an imaging device installed in a smartphone. The imaging device includes a camera for capturing a still image, a video camera for capturing a moving image, and the like.

The light-emitting module 100 includes the light source 1, a first light-transmissive member 2 including a first lens 20 disposed above the light source 1, and a second light-transmissive member 3 including a second lens 30 disposed above the first light-transmissive member 2. The light source 1, the first lens 20, and the second lens 30 are spaced apart from one another.

In the example illustrated in FIG. 1 and FIG. 2, a center Q of the light source 1, an optical axis 20C of the first lens 20, and an optical axis 30C of the second lens 30 coincide with one another in a top view.

Further, in the example illustrated in FIG. 2, the light-emitting module 100 further includes a wiring substrate 4 and an electronic component 5. The light source 1 and a plurality of electronic components 5 are disposed on an upper surface 4a of the wiring substrate 4.

A light incident surface 310 of the second lens 30 includes a first region 301 overlapping the optical axis 30C of the second lens 30 and overlapping at least the light source 1 in a top view, and a second region 302 surrounding the first region 301 in a top view. The second region 302 surrounds the entire circumference of the first region 301. The second lens 30 includes, in the second region 302, an optical functional portion 320 having a positive refractive power. In FIG. 1, the reference numeral of the second region 302 and the reference numeral of the optical functional portion 320 are illustrated together so as to indicate that the light incident surface 310 of the second lens includes the optical functional portion 320 in the second region 302. The refractive power of the optical functional portion 320 is greater than the refractive power of the second lens 30 in the first region 301.

For example, a portion of light emitted from the light source and transmitted through the first light-transmissive member without being affected by the lens function of the first lens becomes stray light and cannot contribute to light emitted from the light-emitting module. This would reduce the light extraction efficiency of the light-emitting module.

In the light-emitting module 100 according to the present embodiment, the light source 1 emits light L. The light L includes light L1 transmitted through the first lens 20 and light L2 transmitted through the first light-transmissive member 2 without being affected by the lens function of the first lens 20. Of the light L, the light L2 transmitted through the first light-transmissive member 2 without being affected by the lens function of the first lens 20 passes through the optical functional portion 320 having a refractive power greater than the refractive power of the first region 301 of the second light-transmissive member 3 and is thus guided in a direction toward the optical axis 30C of the second lens 30. Accordingly, the light L2 transmitted through the first light-transmissive member 2 without being affected by the lens function of the first lens 20 contributes to light emitted from the light-emitting module 100. As a result, as compared to a case in which the light L2 does not contribute to light emitted from the light-emitting module 100, stray light is reduced and the light extraction efficiency is increased. In the present embodiment, the light-emitting module 100 having high light extraction efficiency can be provided. For example, when the light-emitting module 100 is used as a light source for a flash of an imaging device installed in a smartphone, a high-quality image can be captured by using bright irradiation light while reducing power consumption of the smartphone.

The “refractive power” refers to the degree to which incident light is bent, that is, the traveling direction of light is changed. The “positive refractive power” is refractive power that converges light. The “negative refractive power” is refractive power that diverges light. In FIG. 2, the light L2 emitted from the light source 1 travels in a direction away from the optical axis 30C of the second lens 30, reaches the optical functional portion 320, and is then refracted toward the optical axis 30C of the second lens 30 by the positive refractive power. The degree to which the traveling direction of incident light is bent is not limited to the degree to which the traveling direction of the light is bent by refraction, and may be the degree of to which the traveling direction of the light is bent by an optical phenomenon other than refraction, such as diffraction or reflection. For example, in a case where the optical functional portion 320 includes a Fresnel lens, a portion of light incident on the Fresnel lens is reflected by a projection on the surface of the Fresnel lens, and is bent in a desired direction. The degree to which the traveling direction of the light is bent by such reflection is also included in the refractive power.

There are a space between the light source 1 and the first lens 20 and a space between the first lens 20 and the second lens 30. A difference in refractive index between air and the first lens 20 and a difference in refractive index between air and the second lens 30 are each greater than a difference in refractive index between the first lens 20 and the second lens 30. A greater refractive power corresponding to a difference in refractive index is exhibited when the light source 1, the first lens 20, and the second lens 30 are spaced apart from one another than when the light source 1, the first lens 20, and the second lens 30 are not spaced apart from one another. The greater the refractive power is, the smaller the curvature of each of the surfaces of the first lens 20 and the second lens 30 can be. As a result, in the light-emitting module 100, the first lens 20 and the second lens 30 can be easily manufactured, and thus the light-emitting module 100 can be easily manufactured. In addition, the thicknesses of the first lens 20 and the second lens 30 in the Z direction can be reduced, and thus the thickness of the light-emitting module 100 can be reduced.

In the example illustrated in FIG. 1 and FIG. 2, the shape of the light-emitting module 100 in a top view is a substantially circular shape. However, the shape of the light-emitting module 100 in a top view may be a substantially rectangular shape, a substantially elliptical shape, a substantially polygonal shape, or the like.

In the example illustrated in FIG. 3, the outer shape of the light source 1 in a top view is a substantially rectangular shape. The light source 1 includes a plurality of light-emitting parts 10. The light source 1 illustrated in FIG. 1 to FIG. 3 includes nine light-emitting parts 10 having respective light-emitting surfaces 11. The light-emitting surfaces 11 refer to main light extraction surfaces of the light-emitting parts 10. A region including the light-emitting surfaces 11 corresponds to a light-emitting region 16. When there is one light-emitting surface 11, the light-emitting region 16 is a region surrounded by the outer edges of the light-emitting surface 11. When the light source 1 includes a plurality of light-emitting surfaces 11, the light-emitting region 16 is a region formed by connecting outermost outer edges of the plurality of light-emitting surfaces 11 in a top view. That is, lines connecting the outermost outer edges of the light-emitting surfaces 11 in a top view are outer edges 16G of the light-emitting region 16. In the example illustrated in FIG. 3, the light-emitting region 16 includes nine light-emitting surfaces 11. The shape of the outer edge 16G of the light-emitting region 16 is a substantially rectangular shape in a top view and includes four corners 17. In the light source 1, light L is emitted from the light-emitting surface 11 included in each of the plurality of light-emitting parts 10 toward the first lens 20. The number of the light-emitting parts 10 included in the light source 1 is not limited to nine, but is sufficiently at least one.

Each of the plurality of light-emitting parts 10 can be individually driven to emit light. By controlling the distribution of supply of a current to the plurality of light-emitting parts 10, the light distribution of light emitted from light-emitting module 100 can be controlled.

In the light-emitting module 100, the plurality of light-emitting parts 10 can be turned on individually or in groups. The light-emitting module 100 can increase the contrast on an irradiation surface irradiated with light L from the light source 1 by individually turning on the plurality of light-emitting parts 10 with desired brightness or turning on the plurality of light-emitting parts 10 in groups. Further, the light-emitting module 100 can perform partial irradiation on the illumination surface by individually turning on the plurality of light-emitting parts 10 or turning on the plurality of light-emitting parts 10 in groups. The “partial irradiation” means irradiating a partial region of the irradiation surface with light.

In the partial irradiation, a partial region of the irradiation surface is irradiated with light. Therefore, the outer edge of irradiation light on the irradiation surface is preferably clear such that light irradiated onto a desired region is made conspicuous. That is, it is preferable that there is a large difference in illuminance of irradiation light between a desired region to be irradiated with light and a region other than the desired region. In other words, it is preferable that the amount of stray light around irradiation light is small in a desired region of the irradiation surface to be irradiated with light. By reducing the amount of stray light on the irradiation surface, the light-emitting module 100 can reduce the amount of light irradiated onto a region other than a desired region while irradiating the desired region with light L. Accordingly, a difference in illuminance of irradiation light between a desired region to be irradiated with light and a region other than the desired region can be increased, so that the light irradiated onto the desired region can be made conspicuous. That is, the contrast of irradiation light on the irradiation surface can be increased.

When the light-emitting module 100 is used as a flash light source of an imaging device, the light-emitting module 100 can switch between a wide-angle mode and a narrow-angle mode. In the wide-angle mode, all the light-emitting parts 10 are caused to emit light, and in the narrow-angle mode, only a light-emitting part 10 located near the center of the light-emitting region 16 is caused to emit light, and light-emitting parts 10 located near the outer edge 16G of the light-emitting region 16 are caused not to emit light. For example, in the case of the nine light-emitting parts 10 illustrated in FIG. 3, only a light-emitting part 10-5 is caused to emit light in the narrow-angle mode, and all other light-emitting parts 10-1 to 10-9 are caused to emit light in the wide-angle mode. In the narrow-angle mode, the light distribution angle is narrower than that in the wide-angle mode. In the light-emitting module 100, irradiation light can be switched in accordance with the wide-angle mode or the narrow-angle mode. Thus, by using light emitted from the light-emitting module 100, the imaging device can capture an image in accordance with a photographing mode such as close-up photography or telephoto photography.

### (Light Source 1)

A plurality of light-emitting parts 10 are arranged in the lengthwise direction, in the widthwise direction, or in a matrix in a top view. The plurality of light-emitting parts 10 illustrated in FIG. 3 include the nine light-emitting parts 10, which are the light-emitting parts 10-1, 10-2, 10-3, 10-4, 10-5, 10-6, 10-7, 10-8, and 10-9. The nine light-emitting parts 10 are arranged along the X direction, or are arranged along the X direction and the Y direction. The nine light-emitting parts 10 illustrated in FIG. 3 are arranged along the X direction and the Y direction.

The light-emitting part 10-1 has a light-emitting surface 11-1, the light-emitting part 10-2 has a light-emitting surface 11-2, the light-emitting part 10-3 has a light-emitting surface 11-3, the light-emitting part 10-4 has a light-emitting surface 11-4, and the light-emitting part 10-5 has a light-emitting surface 11-5. The light-emitting part 10-6 has a light-emitting surface 11-6, the light-emitting part 10-7 has a light-emitting surface 11-7, the light-emitting part 10-8 has a light-emitting surface 11-8, and the light-emitting part 10-9 has a light-emitting surface 11-9. The light-emitting surface 11-1 to the light-emitting surface 11-9 are preferably disposed inward of the second lens 30 (inward relative to the contour of the second lens 30) in a top view. Each of the light-emitting parts 10 overlaps a corresponding one of light-emitting surfaces 11 in a top view. Thus, the reference numeral of each of the light-emitting parts 10 and the reference numeral of a corresponding light-emitting surface 11 are illustrated together in FIG. 3. Further, in the following description, if two or more components substantially coincide with each other or overlap each other, reference numerals can be illustrated together.

The shape of a light-emitting surface 11 in a top view is a substantially rectangular shape. A first width Wx represents the width of the light-emitting surface 11 in the X direction, and a second width Wy represents the width of the light-emitting surface 11 in the Y direction. The first width Wx and the second width Wy are, for example, 50 μm or more and 2,000 μm or less, and preferably 200 μm or more and 1,000 μm or less. The first width Wx and the second width Wy can be substantially equal to each other or can be different from each other. A plurality of light-emitting surfaces 11 may include light-emitting surfaces 11 having different first widths Wx and/or different second widths Wy. The shape of the light-emitting surface 11 in a top view may be a substantially circular shape or a substantially elliptical shape, or may be a polygonal shape such as a substantially triangular shape or a substantially hexagonal shape.

In the present embodiment, light-emitting surfaces 11 of adjacent light-emitting parts 10 are arranged at a predetermined interval in a top view. Each of a first light-emitting surface interval dx in the X direction and a second light-emitting surface interval dy in the Y direction corresponds to the predetermined interval. From the viewpoint of light emission characteristics of the light-emitting module 100, the narrower the first light-emitting surface interval dx and the second light-emitting surface interval dy, the more preferable. However, there are limits to the intervals at which a plurality of light-emitting parts 10 are mounted. To exhibit good light emission characteristics while providing intervals at which the plurality of light-emitting parts 10 can be mounted, the first light-emitting surface interval dx and the second light-emitting surface interval dy are both preferably 10 μm or more and 50 μm or less.

### (Light-Emitting Part 10)

The light-emitting part 10-1 illustrated in FIG. 4 is disposed on the surface on the +Z side of the wiring substrate 4, with the upper surface of the light-emitting part 10-1 serving as the light-emitting surface 11-1 and the surface opposite to the light-emitting surface 11-1 serving as a mounting surface. The light-emitting part 10-1 includes a light-emitting element 12, a wavelength conversion member 14 provided on the light-emitting element 12, and a light-shielding member 15 covering the lateral surfaces of the light-emitting element 12 and the lateral surfaces of the wavelength conversion member 14 except for the upper surface of the wavelength conversion member 14. In other words, the lateral surfaces of the light-emitting element 12 and the lateral surfaces of the wavelength conversion member 14 are covered by the light-shielding member 15. With this configuration, light leaking from the lateral surfaces of the light-emitting element 12 and the lateral surfaces of the wavelength conversion member 14 is reduced, and thus a desired region can be irradiated with light from the light source 1.

The light-shielding member 15 is continuous between adjacent light-emitting parts 10 of the plurality of the light-emitting parts 10 included in the light source 1. That is, the light-shielding member 15 integrally holds a plurality of the light-emitting elements 12 and a plurality of wavelength conversion members 14. With this configuration, the plurality of the light-emitting parts 10 can be collectively mounted and the interval between adjacent light-emitting surfaces 11 can be narrowed, as compared to when light-shielding members 15 are not continuous between adjacent light-emitting parts 10 and each of the plurality of the light-emitting parts 10 is individually mounted.

Light-emitting surfaces 11 of adjacent light-emitting parts 10 of the nine light-emitting parts 10 are spaced apart from each other by the light-shielding member 15 in the illustrated example; alternatively, the adjacent light-emitting surfaces 11 may be continuous with each other. For example, one wavelength conversion member 14 can cover the entirety of a plurality of light-emitting elements 12. In this case, the first light-emitting surface interval dx and the second light-emitting surface interval dy are 0.

At least one pair of positive and negative electrodes 13 are provided on the surface (lower surface) of the light-emitting element 12 opposite the light-emitting surface 11-1.

The light-emitting element 12 includes various semiconductors such as group III-V compound semiconductors and group II-VI compound semiconductors. As the semiconductors, nitride-based semiconductors such as In_{X}Al_{Y}Ga_{1-X-Y}N (0≤X, 0≤Y, X+Y≤1) are preferably used, and InN, AlN, GaN, InGaN, AlGaN, InGaAlN, and the like can also be used. The light-emitting element 12 is, for example, an LED or a laser diode (LD). The peak emission wavelength of the light-emitting element 12 is preferably 400 nm or more and 530 nm or less, more preferably 420 nm or more and 490 nm or less, and even more preferably 450 nm or more and 475 nm or less, from the viewpoint of emission efficiency, excitation of a wavelength conversion substance, which will be described below, and the like.

The wavelength conversion member 14 is a member having, for example, a substantially rectangular shape in a top view. The wavelength conversion member 14 is disposed so as to cover the upper surface of the light-emitting element 12. The wavelength conversion member 14 includes a wavelength conversion substance that converts a wavelength of at least a portion of light from the light-emitting element 12. The wavelength conversion member 14 can be formed by using a light-transmissive resin material or an inorganic material such as a ceramic or glass. As the resin material, a thermosetting resin such as a silicone resin, a silicone-modified resin, an epoxy resin, an epoxy-modified resin, or a phenol resin can be used. In particular, a silicone resin or a modified resin thereof having high light resistance and heat resistance is preferable. As used herein, the term “light-transmissive” means that 60% or more of the light from the light-emitting element 12 is preferably transmitted. Further, a thermoplastic resin such as a polycarbonate resin, an acrylic resin, a methylpentene resin, or a polynorbornene resin can be used for the wavelength conversion member 14. For example, the wavelength conversion member 14 can be a resin material, a ceramic, glass, or the like containing a wavelength conversion substance, a sintered body of a wavelength conversion substance, or the like. Further, the wavelength conversion member 14 can include a light diffusing substance described below in the above-described resin. Further, the wavelength conversion member 14 can be a multilayer member in which a resin layer containing a wavelength conversion substance or a light diffusing substance is disposed on the surface on the +Z side of a formed body of a resin, a ceramic, glass, or the like.

Examples of a wavelength conversion substance included in the wavelength conversion member 14 include yttrium aluminum garnet based phosphors (for example, (Y, Gd)₃ (Al,Ga)₅O₁₂:Ce), lutetium aluminum garnet based phosphors (for example, Lu₃(Al,Ga)₅O₁₂:Ce), terbium aluminum garnet based phosphors (for example, Tb₃(Al,Ga)₅O₁₀:Ce), CCA based phosphors (for example, Ca₁₀(PO₄)₆Cl₂:Eu), SAE based phosphors (for example, Sr₄Al₁₄O₂₅:Eu), chlorosilicate based phosphors (for example, Ca₈MgSi₄O₁₆Cl₂:Eu), silicate based phosphors (for example, (Ba,Sr,Ca,Mg)₂SiO₄:Eu), oxynitride based phosphors such as β-SiAlON based phosphors (for example, (Si,Al)₃(O,N)₄:Eu) and α-SiAlON based phosphors (for example, Ca(Si,Al)₁₂(O,N)₁₆:Eu), nitride based phosphors such as LSN based phosphors (for example, (La,Y)₃Si₆N₁₁:Ce), BSESN based phosphors (for example, (Ba,Sr)₂Si₅N₈:Eu), SLA based phosphors (for example, SrLiAl₃N₄:Eu), CASN based phosphors (for example, CaAlSiN₃:Eu), and SCASN based phosphors (for example, (Sr,Ca)AlSiN₃:Eu), fluoride based phosphors such as KSF based phosphors (for example, K₂SiF₆:Mn), KSAF based phosphors (for example, K₂(Si₁₋ₓAlₓ)F₆₋ₓ:Mn, where x satisfies 0<x<1), and MGF based phosphors (for example, 3.5MgO·0.5MgF₂·GeO₂:Mn), quantum dots having a Perovskite structure (for example, (Cs,FA,MA) (Pb,Sn) (F,Cl,Br,I)₃, where FA and MA represent formamidinium and methylammonium, respectively), II-VI quantum dots (for example, CdSe), III-V quantum dots (for example, InP), and quantum dots having a chalcopyrite structure (for example, (Ag,Cu) (In,Ga) (S,Se)₂). The wavelength conversion substances described above are particles. One of these wavelength conversion substances may be used alone, or two or more of these wavelength conversion substances may be used in combination.

In the present embodiment, the light source 1 uses a blue LED as the light-emitting element 12. The wavelength conversion member 14 includes a wavelength conversion substance that converts the wavelength of the light emitted from the light-emitting element 12 into the wavelength of yellow. Accordingly, the light source 1 can emit white light. The wavelength or the chromaticity of light emitted from the light source 1 may be appropriately selected according to the application of the light-emitting module 100. The wavelength conversion member 14 includes a light diffusing substance. For example, as the light diffusing substance, titanium oxide, barium titanate, aluminum oxide, silicon oxide, or the like can be used.

The light-shielding member 15 is a member covering the lateral surfaces of the light-emitting element 12 and the lateral surfaces of the wavelength conversion member 14. The light-shielding member 15 directly or indirectly covers the lateral surfaces of the light-emitting element 12 and the lateral surfaces of the wavelength conversion member 14. The upper surface of the wavelength conversion member 14 in FIG. 4 is exposed through the light-shielding member 15, and is the light-emitting surface 11-1 of the light-emitting part 10-1. To improve the light extraction efficiency, the light-shielding member 15 is preferably formed of a member having a high light reflectance. For example, a resin material containing a light reflective substance such as a white pigment can be used for the light-shielding member 15. Further, for example, the light-shielding member 15 may be a light reflective member composed of an inorganic material including boron nitride or alkali metal silicate. In this case, the light-shielding member 15 can further include titanium oxide or zirconium oxide.

Examples of the light reflective substance include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, silicon oxide, and the like. It is preferable to use one of the above substances alone or a combination of two or more of the above substances. Further, as the resin material, it is preferable to use a base material including a resin material whose main component is a thermosetting resin such as an epoxy resin, an epoxy-modified resin, a silicone resin, a silicone-modified resin, or a phenol resin. The light-shielding member 15 may be configured with a member having light transmissivity or light absorbability with respect to visible light as necessary. A member having light absorbability includes, for example, carbon black.

The light-emitting part 10 is electrically connected to wiring 41 of the wiring substrate 4. The wiring substrate 4 includes the wiring 41 on the surface of the wiring substrate 4. The wiring substrate 4 can include the wiring 41 inside the wiring substrate 4. The light-emitting part 10 and the wiring substrate 4 are electrically connected to each other by connecting the wiring 41 of the wiring substrate 4 to at least the positive and negative electrodes 13 of the light-emitting element 12 via electrically-conductive members 42. The configuration, the size, and the like of the wiring 41 of the wiring substrate 4 are set in accordance with the configuration, the size, and the like of the electrodes 13 of the light-emitting element 12.

The wiring substrate 4 is a plate-shaped member having a substantially circular shape in a top view. The wiring substrate 4 is a substrate including wiring on which the light source 1 and the electronic components 5 can be mounted. The shape of the wiring substrate 4 in a top view can be a substantially rectangular shape, a substantially elliptical shape, a substantially polygonal shape, or the like.

As a base material of the wiring substrate 4, an insulating material is preferably used, and also a material that does not easily transmit light emitted from the light-emitting part 10, external light, or the like is preferably used. In the present specification, the external light is not limited to sunlight, and includes all lights that enter the light-emitting module 100 from the outside of the light-emitting module 100. Further, a material having a certain strength is preferably used for the wiring substrate 4. Specifically, as the base material of the wiring substrate 4, a ceramic such as alumina, aluminum nitride, mullite, or silicon nitride, or a resin such as a phenol resin, an epoxy resin, a polyimide resin, a bismaleimide-triazine resin (BT resin), polyphthalamide, or a polyester resin can be used.

The wiring 41 can be composed of at least one of copper, iron, nickel, tungsten, chromium, aluminum, silver, gold, titanium, palladium, rhodium, or an alloy thereof. In addition, a layer of silver, platinum, aluminum, rhodium, gold, an alloy thereof, or the like can be provided on the surface layer of the wiring 41 from the viewpoint of at least one of wettability or light reflectivity of the electrically-conductive members 42.

### First Light-Transmissive Member 2

The first light-transmissive member 2 illustrated in FIG. 2 includes a first support portion 21 that supports the first lens 20. In addition, in the present embodiment, the first light-transmissive member 2 includes a leg portion 22 located outward of the first lens 20 and continuous with the first support portion 21 in a top view.

The first light-transmissive member 2 has a substantially circular shape in a top view. However, the first light-transmissive member 2 may have a substantially rectangular shape, a substantially elliptical shape, a substantially polygonal shape, or the like in a top view. Further, the first light-transmissive member 2 may have a rotationally symmetric shape in a top view. Considering that an imaging range of a general imaging device is substantially rectangular, it is preferable that the first light-transmissive member 2 has a four-fold rotationally symmetric shape or a two-fold rotationally symmetric shape in a top view. In the first lens 20, the radii of curvature of a light incident surface 20a and a light exit surface 20b, the magnitude relationship between the radii of curvature, the thickness of the lens in the Z direction, and the like can be appropriately changed.

The first support portion 21 is an annular portion located outward of the first lens 20 in a top view. The “annular shape” in the present embodiment includes: a substantially circular shape in a plan view; a substantially elliptical shape in a plan view; an annular shape having outer edges including straight line(s) and curved line(s), such as a substantially semicircular shape, a substantially circular sector shape, or a substantially semi-elliptical shape in a plan view; or a polygonal annular shape such as a substantially square shape or a substantially polygonal shape in a plan view. In the example illustrated in FIG. 2, the first support portion 21 is located outward of the first lens 20 and has a convex surface on the +Z side (hereinafter may be referred to as an “upper side” or “upward”). The first support portion 21 does not necessarily have a convex surface, and may have a flat surface, a concave surface, a rough surface, or the like. The first light-transmissive member 2 is fixed to the wiring substrate 4 by a first adhesive member 23 disposed between a bottom surface 22a of the leg portion 22 and the upper surface 4a of the wiring substrate 4. The leg portion 22 may be omitted, and the first support portion 21 may also function as the leg portion 22.

The leg portion 22 is located outward of the first lens 20 and extends to the −Z side (hereinafter may be referred to as a “lower side” or “downward”). The leg portion 22 supports the first lens 20 and the first support portion 21 with the first lens 20 located above the light source 1 and the first support portion 21 located outward of the first lens 20 in a top view.

The first lens 20 has the light incident surface 20a on which light from the light source 1 is incident and the light exit surface 20b through which light exits from the first lens 20. The light incident surface 20a protrudes in a direction (to the −Z side) toward the light source 1. The light exit surface 20b protrudes in a direction (to the +Z side) opposite to the direction toward the light source 1. The light incident surface 20a and the light exit surface 20b of the first lens 20 form a biconvex lens. However, the first lens 20 is not limited to a biconvex lens, and may be a plano-convex lens, a biconcave lens, a plano-concave lens, a Fresnel lens, a combined lens composed of a plurality of lenses, an array lens, a meniscus lens, an aspherical lens, a cylindrical lens, or the like.

In the present embodiment, the curvature of the light incident surface 20a is greater than the curvature of the light exit surface 20b. Thus, light L1 transmitted through the first lens 20 can be efficiently condensed by the first lens 20. When the curvature of the light incident surface 20a of the first lens 20 is greater than the curvature of the light exit surface 20b of the first lens 20, an amount of light, of light L from the light source 1, that passes through the first lens 20 decreases as compared to when the curvature of the light incident surface 20a of the first lens 20 is smaller than the curvature of the light exit surface 20b of the first lens 20. However, in the present embodiment, light L2, of the light L from the light source 1, that does not pass through the first lens 20 is efficiently guided by the optical functional portion 320 of the second lens 30 in a direction toward the optical axis 30C of the second lens 30. Therefore, with the curvature of the light incident surface 20a of the first lens 20 greater than the curvature of the light exit surface 20b of the first lens 20, the light L from the light source 1 is affected by both a light-condensing function of the first lens 20 and a light-guiding function of the optical functional portion 320 of the second lens 30, and thus the light utilization efficiency is improved. Accordingly, the light extraction efficiency of the light-emitting module 100 is increased.

In FIG. 2, an inclination angle φ of a tangent line to a lower surface 21a of the first support portion 21 relative to a plane 21b parallel to the upper surface 4a of the wiring substrate 4 is preferably 70 degrees or less. For example, if the inclination angle φ exceeds 70 degrees, an angle formed by the plane 21b and a light beam emitted from the light source 1 and transmitted through the first support portion 21 decreases (in other words, approaches 0 degrees), and thus the light beam would not be incident on the second lens 30. If the amount of light incident on the second lens 30 decreases, the light extraction efficiency of the light-emitting module 100 would be decreased. By setting the inclination angle φ to 70 degrees or less, the angle formed by the plane 21b and the light beam emitted from the light source 1 and transmitted through the first support portion 21 increases (in other words, approaches 90 degrees). This allows for increasing the probability of the light beam entering the second lens 30, so that the amount of light entering the second lens 30 increases. Accordingly, the light extraction efficiency of the light-emitting module 100 can be increased.

The first light-transmissive member 2 includes at least one of: a resin material, such as a polycarbonate resin, an acrylic resin, a silicone resin, or an epoxy resin; or a glass material, which have light transmissivity with respect to light emitted from the light source 1. The first lens 20, the first support portion 21, and the leg portion 22 are connected to one another as a single body. As used herein, the “light transmissivity” of the first light-transmissive member 2 refers to a property of transmitting 60% or more of the light from the light source 1.

### Second Light-Transmissive Member 3

The second light-transmissive member 3 illustrated in FIG. 2 includes a second support portion 31 that supports the second lens 30. The second support portion 31 is located on the entire outer periphery of the second lens 30 in a top view. The second lens 30 and the second support portion 31 are integrally molded with each other.

In the example illustrated in FIG. 1, the shape of the second light-transmissive member 3 in a top view is a substantially circular shape. However, the shape of the second light-transmissive member 3 in a top view may be a substantially rectangular shape, a substantially elliptical shape, a substantially polygonal shape, or the like.

The shape of an outer edge 301G of the first region 301 in a top view is a substantially circular shape. The shape of each of the inner edge and an outer edge 302G of the second region 302 in a top view is a substantially circular shape. In other words, the second region 302 is an annular region. That is, the first region 301 is located inward of the annular second region 302 in a top view. However, the shapes of the inner edge and the outer edge of the second region 302 can be different from each other in a top view, and can each be a substantially rectangular shape, a substantially elliptical shape, a substantially polygonal shape, or the like. In the present embodiment, the inner edge of the second region 302 coincides with the outer edge 301G of the first region 301.

The second support portion 31 is a cylindrical portion having a substantially circular shape in a top view. However, the shape of the second support portion 31 in a top view can be a substantially elliptical shape, a substantially polygonal shape, or the like.

The second lens 30 illustrated in FIG. 2 is disposed over the first lens 20 so as to overlap the light source 1 and the first lens 20 in a top view. The second support portion 31 is provided so as to extend downward from the outer edge of the second lens 30. The second support portion 31 supports the second lens 30 such that the second lens 30 is disposed above the first lens 20. The second light-transmissive member 3 is fixed to the wiring substrate 4 by a second adhesive member 32 disposed between an inner lateral surface 31a of the second support portion 31 and an outer lateral surface 4b of the wiring substrate 4. The first adhesive member 23 and the second adhesive member 32 may be integrally formed with each other.

The light incident surface 310 of the second lens 30 illustrated in FIG. 2 is a concave surface. By forming the light incident surface 310 to be a concave surface, the area of the second region 302 facing the first light-transmissive member 2 increases as compared to when the light incident surface of the second lens is a substantially flat surface. Thus, of light L2 transmitted through the first light-transmissive member 2 without being affected by the lens function of the first lens 20, light passing through the optical functional portion 320 increases. Accordingly, a large portion of light L2 transmitted through the first light-transmissive member 2 without being affected by the lens function of the first lens is guided by the optical functional portion 320 in a direction toward the optical axis 30C of the second lens 30, and contributes to light emitted from the light-emitting module 100. As a result, the light extraction efficiency of the light-emitting module 100 is increased.

As will be described below, the light incident surface 310 includes a plurality of projections 311 and a plurality of projections 321, and thus includes an irregular surface when viewed microscopically. That is, the light incident surface 310 has a shape in which fine irregularities are superimposed on the concave surface. When the depth of the concave surface of the light incident surface 310 is defined as a distance R between a lower end 310a and an upper end 310b of the light incident surface 310 in the Z direction, the distance R indicating the depth of the concave surface of the light incident surface 310 is much greater than the heights of the plurality of projections 311 and the plurality of projections 321 in the Z direction. Thus, it can be said that the light incident surface 310 is the concave surface when viewed as a whole or when viewed macroscopically. The light incident surface 310 is not limited to the concave surface when viewed as a whole or when viewed macroscopically, and may be a flat surface or a convex surface.

The optical functional portion 320 is located at the light incident surface 310 of the second lens 30. The optical functional portion 320 includes the plurality of projections 321. For example, the plurality of projections 321 form a Fresnel lens surface, and the Fresnel lens surface of the optical functional portion 320 guides incident light L2 in a direction toward the optical axis 30C of the second lens 30. At least a portion of the light L2 guided in a direction toward the optical axis 30C of the second lens 30 overlaps, on the irradiation surface, irradiation light emitted from the light source 1. The direction toward the optical axis 30C of the second lens 30 is, for example, a direction substantially parallel to light L1 emitted from the same light-emitting part 10 and affected by the function of the first lens 20. In this case, the term “substantially parallel” may include a deviation within ±25° with respect to 0°. The light L2 is guided by the optical functional portion 320 substantially in parallel to the light L1, and thus, on the irradiation surface, the light L2 can contribute to light emitted from the light-emitting module 100 together with the light L1. By using the Fresnel lens surface, the refractive power of the optical functional portion 320 can be increased without increasing the curvature of the optical functional portion 320. Accordingly, in the light-emitting module 100, the thickness of the optical functional portion 320 of the second lens 30 in the Z direction is small. In addition, the light L can be guided in a direction toward the optical axis 30C of the second lens 30. However, the optical functional portion 320 does not necessarily include the plurality of projections 321, and for example, the convex surface may guide the light L2 in a direction toward the optical axis 30C of the second lens 30.

As illustrated in FIG. 1, the optical functional portion 320 overlaps the corners 17 of the light-emitting region 16 in a top view. Of light L diffused at the corners 17 of the light-emitting region 16, light L2 is guided by the optical functional portion 320 in a direction toward the optical axis 30C of the second lens 30. Therefore, of the light L diffused at the corners 17 of the light-emitting region 16, light that becomes stray light is reduced, and thus the light utilization efficiency is improved. Accordingly, the light extraction efficiency of the light-emitting module 100 is increased.

The first region 301 and the optical functional portion 320 of the light incident surface 310 of the second lens 30 includes a plurality of projections 331. The plurality of projections 331 are concentrically arranged on the light incident surface 310. The first region 301 includes the plurality of projections 311 among the plurality of projections 331, and the optical functional portion 320 includes the plurality of projections 321 among the plurality of projections 331. The plurality of projections 321 are arranged concentrically around the optical axis 30C. The projections 321 each have a Fresnel shape having a light-transmitting surface and a total reflection surface located outward of the light-transmitting surface (on the side farther from the optical axis 30C).

In the example illustrated in FIG. 5A and FIG. 5B, in a cross section of the second lens 30 including the optical axis 30C of the second lens 30, a first angle θa at which two lines forming one of the projections 321 of the optical functional portion 320 meet is smaller than a second angle θb at which two lines forming one of the projections 311 of the first region 301 meet. Light L2 emitted from the light source 1 in a direction away from the optical axis 30C of the second lens 30 is reflected by the total reflection surface of one of the projections 321, and travels in a direction toward the optical axis 30C of the second lens 30. That is, the refractive power of the optical functional portion 320 is greater than the refractive power of the first region 301, and the light L2 is guided to approach the optical axis 30C of the second lens 30. As a result, the light extraction efficiency of the light-emitting module 100 is increased.

In a cross section of the second lens 30 including the optical axis 30C of the second lens 30, the plurality of projections 321 have the same second angle θb. Accordingly, the illuminance distribution of light transmitted through the first region 301 is rotationally symmetric about the optical axis 30C of the second lens 30 on the irradiation surface, and thus light emitted from the light-emitting module 100 is easily controlled.

In the example illustrated in FIG. 2, the outer edge 301G of the first region 301 is located outward of an outer edge 20G of the first lens 20 in a top view. For example, if the outer edge 301G of the first region 301 and the outer edge 20G of the first lens 20 substantially overlap each other in a top view and light passing through the first lens 20 slightly spreads, a portion of the light passing through the first lens 20 would not be affected by the function of the first region 301. By setting the outer edge 301G of the first region 301 to be located outward of the outer edge 20G of the first lens 20 in a top view, almost all lights passing through the first lens 20 and exiting from the light exit surface 20b of the first lens 20 can efficiently enter the first region 301 of the second lens 30 and can be affected by the function of the first region 301. Accordingly, the extraction efficiency of light passing through the first lens 20 is increased. In the present embodiment, the function of the first region 301 includes spreading light. The degree to which light spreads can be controlled by adjusting the shape of the projections 311 of the first region 301.

The optical functional portion 320 of the second light-transmissive member 3 overlaps at least a portion of the first support portion 21 in a top view. Thus, light L2 transmitted through the first support portion 21 of the first light-transmissive member 2 without being affected by the lens function of the first lens 20 is guided by the optical functional portion 320 in a direction toward the optical axis 30C of the second lens 30, and contributes to light emitted from the light-emitting module 100. As a result, the light extraction efficiency of the light-emitting module 100 is increased.

As illustrated in FIG. 5A, first projection intervals p1 between adjacent projections 311 of the plurality of projections 311 are the same as each other. Further, as illustrated in FIG. 5B, second projection intervals p2 between adjacent projections 321 of the plurality of projections 321 are the same as each other. Further, the first projection interval p1 and the second projection interval p2 are the same. Accordingly, the first projection intervals p1 and the second projection intervals p2 are uniform, so that the appearance of the light-emitting module 100 is improved. The first projection intervals p1 between adjacent projections 311 of the plurality of projections 311 are not needed to be strictly the same, and the first projection intervals p1 may be adjusted as appropriate in consideration of optical characteristics. The second projection intervals p2 between adjacent projections 321 of the plurality of projections 321 are not needed to be strictly the same as each other, and the second projection intervals p2 may be adjusted as appropriate in consideration of optical characteristics.

The second light-transmissive member 3 includes at least one of: a resin material, such as a polycarbonate resin, an acrylic resin, a silicone resin, or an epoxy resin; or a glass material, which have light transmissivity with respect to light emitted from the plurality of light-emitting parts 10. The light transmissivity of the first region 301 and the second region 302 of the second light-transmissive member 3 refers to a property of transmitting 60% or more of light from the light source 1.

### (Electronic Component 5)

An electronic component 5 illustrated in FIG. 2 is disposed at a position overlapping the optical functional portion 320 in a top view. The height of each of the projections 311 of the optical functional portion 320 in the Z direction is greater than the height of each of the projections 321 of the first region 301 in the Z direction, and thus the surface roughness of the optical functional portion 320 is greater than the surface roughness of the projections 311 of the first region 301. Therefore, when the electronic component 5 overlaps the optical functional portion 320 in a top view, the electronic component 5 is less likely to be visually recognized. Accordingly, the appearance of the light-emitting module 100 is improved.

The electronic component 5 includes at least one of a Zener diode, a thermistor, a capacitor, an external light sensor, or the like. The electronic component 5 illustrated in FIG. 2 includes, for example, an external light sensor that detects the amount of light that enters the light-emitting module 100 from the outside of the light-emitting module 100 through the first light-transmissive member 2 and the second light-transmissive member 3.

### First Modification

Next, a light-emitting module according to a first modification will be described. The same names and reference numerals as those in the above-described embodiment denote the same or similar members or components, and a detailed description thereof will be omitted as appropriate. The same applies to modifications and embodiments described later.

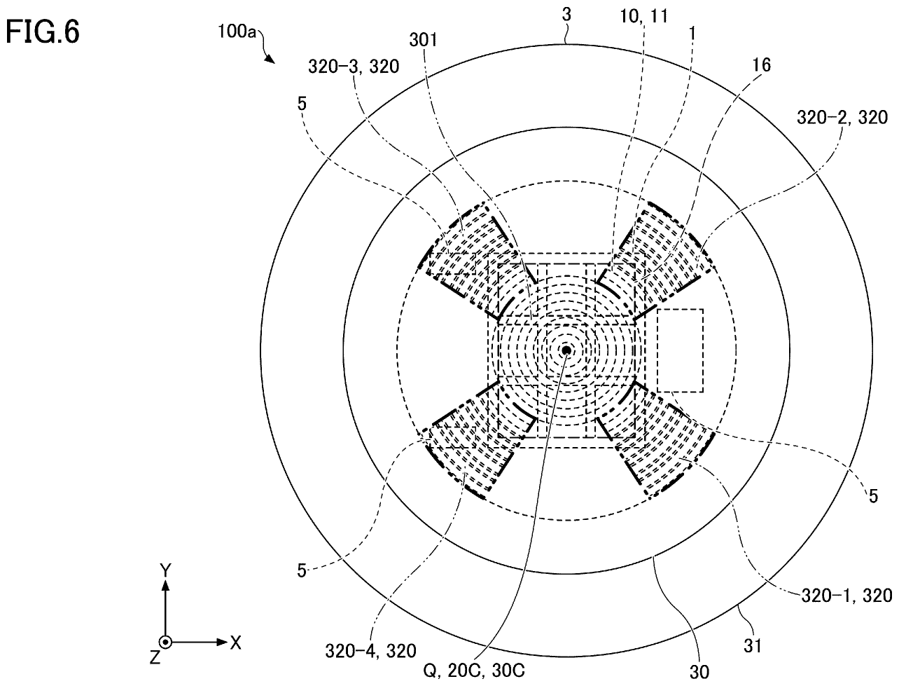

FIG. 6 is a schematic top view of a light-emitting module 100a according to the first modification. The light-emitting module 100a differs from the light-emitting module 100 according to the first embodiment in that optical functional portions 320 are arranged radially around the optical axis 30C of the second lens 30 in a top view.

In the example illustrated in FIG. 6, the optical functional portions 320 include an optical functional portion 320-1, an optical functional portion 320-2, an optical functional portion 320-3, and an optical functional portion 320-4, which are intermittently arranged in an annular region outward of the first region 301 in a top view and along the circumferential direction of the annular region. The optical functional portions 320-1, 320-2, 320-3, and 320-4 overlap the four corners 17 of the light-emitting region 16, respectively, in a top view. A plurality of projections 321 are provided in a region of the annular region where the optical functional portions 320 are arranged. No projections 321 are provided in a region of the annular region where the optical functional portions 320 are not arranged.

In the light-emitting module 100a, of light L, light emitted from the vicinity of each of the corners 17 of the light-emitting region 16, which is light located farthest from the center Q of the light source 1 and the optical axis 20C of the first lens 20, is likely to become stray light. Therefore, as illustrated in FIG. 6, arranging the optical functional portions 320 so as to overlap the four corners 17 of the light-emitting region 16 in a top view allows light L2, of the light L diffused at the corners 17 of the light-emitting region 16, to be incident on the optical functional portions 320 above the corners 17 and to be guided in a direction toward the optical axis 30C of the second lens 30. Accordingly, of the light L diffused at the corners 17 of the light-emitting region 16, light that becomes stray is reduced, and the light utilization efficiency is improved. Accordingly, the light extraction efficiency of the light-emitting module 100a is increased.

The optical functional portions 320-1, 320-2, 320-3, and 320-4 are arranged at equal intervals so as to surround the first region 301 in a top view, and thus a pattern having symmetry about the optical axis 30C of the second lens 30 can be formed by the optical functional portions 320. Accordingly, the appearance of the light-emitting module 100a is improved. In addition, in a case where an electronic component 5 includes a Zener diode, a thermistor, a capacitor, an external light sensor, or the like, the electronic component 5 may be disposed so as to overlap or so as not to overlap any of the optical functional portions 320 in a top view in consideration of the application of the electronic component 5. In the example illustrated in FIG. 6, an electronic component 5 disposed on the +X side of the wiring substrate 4 is an external light sensor, and does not overlap any of the optical functional portions 320 in a top view. Two electronic components 5 arranged on the −X side of the wiring substrate 4 are electronic components other than the external light sensor, and each of these two electronic components 5 overlap a respective one of the optical functional portion 320-3 and the optical functional portion 320-4 in a top view. That is, the two electronic components 5 other than the external light sensor are disposed under the optical functional portion 320. When the external light sensor is disposed so as not to overlap any of the optical functional portions 320 in a top view, external light is less likely to be reflected and diffused by any of the optical functional portions 320, and thus the external light sensor can easily receive external light. When the electronic components 5 other than the external light sensor are arranged so as to overlap the respective optical functional portions 320 in a top view, the electronic components 5 are less likely to be visually recognized when the light-emitting module 100a is viewed from the outside. The number of optical functional portions 320 arranged radially around the optical axis 30C is not limited to four, but may be three or more. As long as a plurality of optical functional portions 320 are arranged radially around the optical axis 30C, the plurality of optical functional portions 320 are not necessarily arranged at constant intervals in the circumferential direction. In the example illustrated in FIG. 6, the optical functional portions 320 overlap the four corners 17 of the light-emitting region 16 in a top view, but the optical functional portions 320 may be disposed so as to overlap the four sides of the light-emitting region 16.

### Second Modification

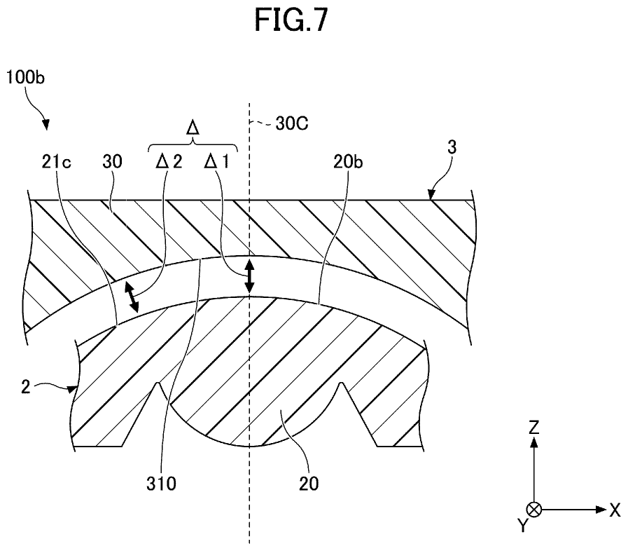

Next, a light-emitting module according to a second modification will be described. FIG. 7 is a schematic cross-sectional view illustrating a surface interval 4 between the first light-transmissive member 2 and the second light-transmissive member 3 of a light-emitting module 100b according to the second modification. FIG. 7 illustrates a part of a cross section of the first light-transmissive member 2 and the second light-transmissive member 3 including an optical axis 30C of a second lens 30.

The light-emitting module 100b differs from the light-emitting module 100 according to the first embodiment in that the surface interval Δ between the first light-transmissive member 2 and the second light-transmissive member 3 is substantially constant. In the present modification, the term “substantially constant” means that (a minimum value of the surface interval Δ)/(a maximum value of the surface interval Δ)≥0.7. In the example illustrated in FIG. 7, the surface interval Δ includes a first surface interval 41 and a second surface interval 42. The first surface interval 41 is an interval between the light exit surface 20b of the first lens 20 of the first light-transmissive member 2 and the light incident surface 310 of the second light-transmissive member 3. The second surface interval 42 is an interval between the light exit surface 21c of the first support portion 21 of the first light-transmissive member 2 and the light incident surface 310 of the second light-transmissive member 3. The first surface interval 41 and the second surface interval 42 are substantially the same. Because the light incident surface 310 of the second lens 30 includes the plurality of projections 311 and the plurality of projections 321, the first surface interval 41 is, more specifically, the shortest distance between a top portion of a corresponding one of the projections 311 and the light exit surface 20b of the first lens 20 of the first light-transmissive member 2. The second surface interval 42 is the shortest distance between a top portion of a corresponding one of the projections 321 and the light exit surface 21c of the first support portion 21 of the first light-transmissive member 2.

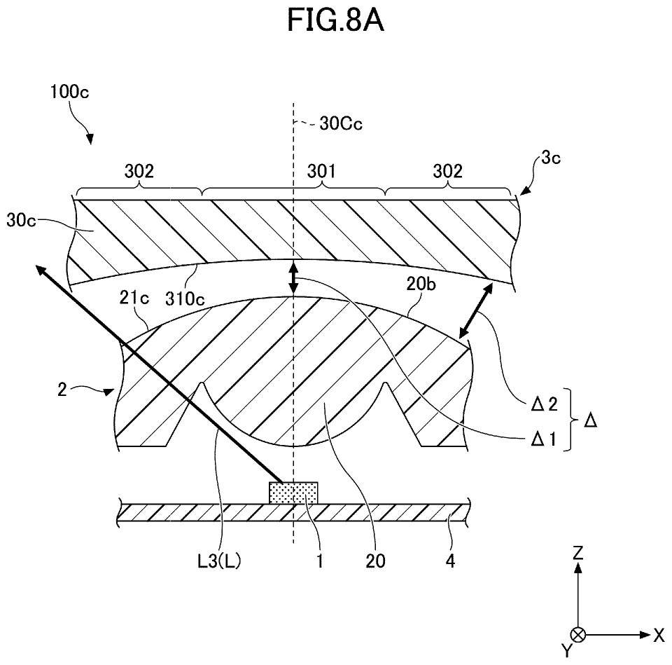

Light-emitting modules according to Comparative Example 1 and Comparative Example 2 will be described. FIG. 8A is a schematic cross-sectional view illustrating a surface interval Δ between a first light-transmissive member 2 and a second light-transmissive member 3c of a light-emitting module 100c according to Comparative Example 1. FIG. 8B is a schematic cross-sectional view illustrating a surface interval Δ between a first light-transmissive member 2 and a second light-transmissive member 3d of a light-emitting module 100d according to Comparative Example 2. In FIG. 8A, light L3 indicated by an arrow represents a portion of light L emitted from a light source 1 of the light-emitting module 100c.

For example, in the light-emitting module 100c according to Comparative Example 1 illustrated in FIG. 8A, a second surface interval 42 becomes greater than a first surface interval 41 as the distance from an optical axis 30Cc of a second lens 30c increases in a direction orthogonal to the optical axis 30Cc. With this configuration, of the light L emitted from the light source 1, the amount of light L3 incident on the second lens 30c of the second light-transmissive member 3c after being transmitted through the first light-transmissive member 2 decreases. Thus, the light extraction efficiency of the light-emitting module 100c may be reduced. In the light-emitting module 100d according to Comparative Example 2 illustrated in FIG. 8B, a second surface interval 42 becomes smaller than a first surface interval 41 as the distance from an optical axis 30Cd of a second lens 30d increases in a direction orthogonal to the optical axis 30Cd. In this configuration, a thickness T of the second lens 30d of the second light-transmissive member 3d in the Z direction is increased, which may lead to increase in the thickness of the light-emitting module 100d in the Z direction.

In contrast, in the light-emitting module 100b, the surface interval Δ is substantially constant, so that the light extraction efficiency of the light-emitting module 100b is increased, and thickness of the light-emitting module 100b in the Z direction is not excessively increased.

### Second Embodiment

Next, a light-emitting module according to a second embodiment will be described.

### Configuration of Light-Emitting Module According to Second Embodiment

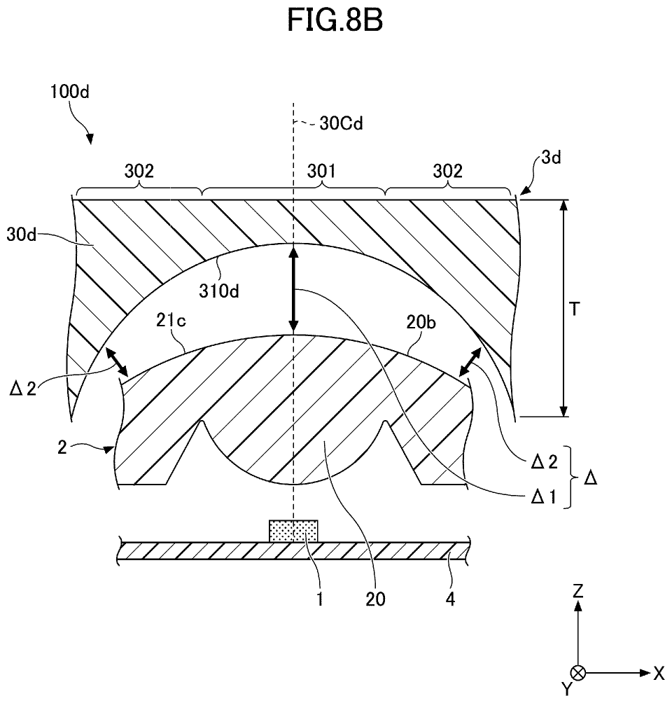

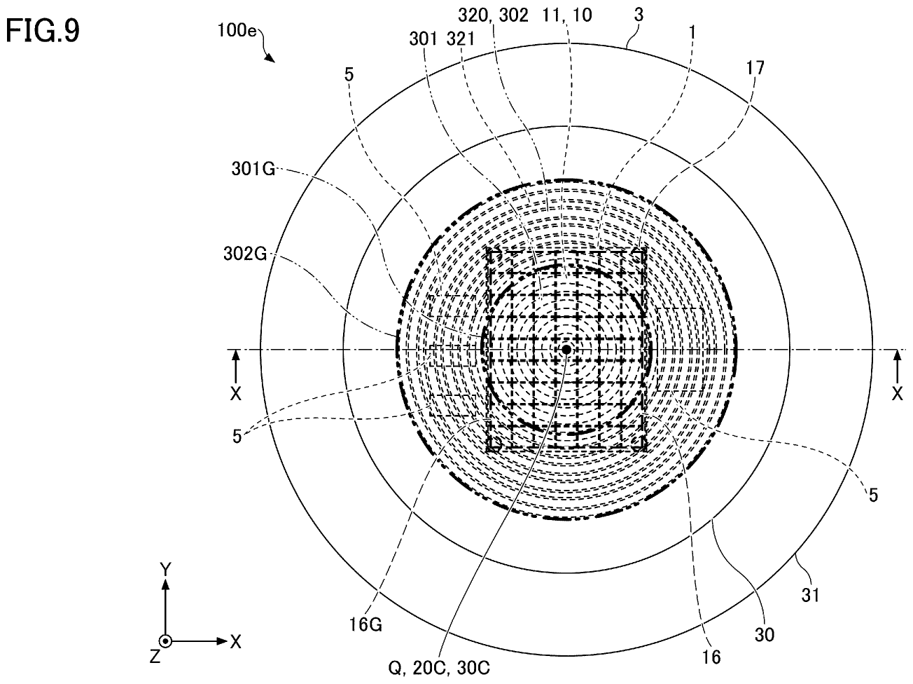

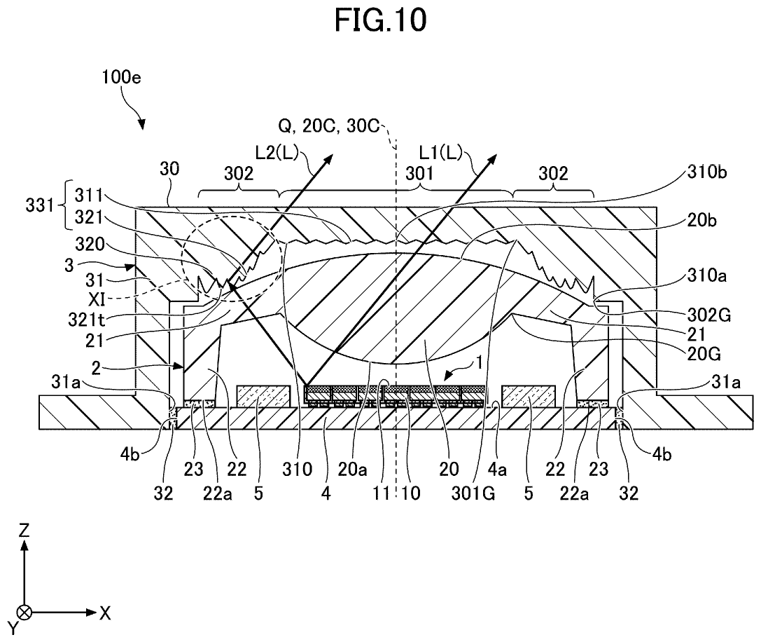

FIG. 9 is a schematic top view illustrating a light-emitting module 100e according to the second embodiment. FIG. 10 is a schematic cross-sectional view taken along line X-X of FIG. 9. FIG. 11A is an enlarged view illustrating a line LN connecting top portions 321t in a region XI of FIG. 10 according to a first example. FIG. 11B is an enlarged view illustrating a line LN connecting top portions 321t in the region XI of FIG. 10 according to a second example. FIG. 11C is an enlarged view illustrating a line LN connecting top portions 321t in the region XI of FIG. 10 according to a third example.

As illustrated in FIG. 10, in the light-emitting module 100e according to the second embodiment, in a cross section of a second lens 30 including an optical axis 30C of the second lens 30, a line connecting respective top portions 321t of a plurality of projections 321 included in an optical functional portion 320 protrudes toward a first lens 20. This configuration is a main difference from the light-emitting module 100 according to the first embodiment.

As illustrated in FIG. 9, a light source 1 of the light-emitting module 100e includes a total of sixty-three light-emitting parts 10 in which seven light-emitting parts 10 are arranged in the X direction and nine light-emitting parts 10 are arranged in the Y direction. Alternatively, as in the light source 1 of the light-emitting module 100 according to the first embodiment, the light source 1 of the light-emitting module 100e may include a total of nine light-emitting parts 10 in which three light-emitting parts 10 are arranged in the X direction and three light-emitting parts 10 are arranged in the Y direction.

FIG. 11A, FIG. 11B, and FIG. 11C are diagrams each illustrating a line LN connecting top portions 321t of a plurality of projections 321. The line LN is an imaginary line that includes an end portion A, an end portion B, and the top portions 321t. The end portion A coincides with an outer edge 301G of a first region 301 of the second lens 30, and the end portion B coincides with an outer edge 302G of a second region 302. In each of FIG. 11A, FIG. 11B, and FIG. 11C, the projections 321 illustrated in the region XI indicated by a dashed line in FIG. 10 are not illustrated, and the top portions 321t, which are the top portions of the projections 321 in the region XI, are indicated by points for the sake of simplicity. In addition, in each of FIG. 11A, FIG. 11B, and FIG. 11C, only one point among a plurality of points is denoted by the reference numeral “321t” in order to simplify the drawings, but each of the plurality of points corresponds to a top portion 321t.

In a cross section of the second lens 30 including the optical axis 30C of the second lens 30, the line LN refers to an entirety of lines connecting adjacent top portions 321t of the plurality of top portions 321t from the end portion A to the end portion B. The line LN connecting the plurality of points corresponding to the plurality of top portions 321t corresponds to a “line connecting the respective top portions 321t of the plurality of projections 321.” As illustrated in FIG. 11A, FIG. 11B, and FIG. 11C, a lowermost top portion C on the −Z side of the protruding shape is located between the end portion A and the end portion B of the protruding shape.

In the first example illustrated in FIG. 11A, top portions 321t are arranged so as to be gradually shifted toward the −Z side from an end portion A toward an end portion B, and thus a line LN protrudes toward the −Z side as a whole. Specifically, among three consecutive top portions 321t, a top portion 321t located in the middle is located on the −Z side relative to an imaginary straight line connecting the other two top portions 321t. Therefore, the line LN protrudes toward the −Z side on which the first lens 20 is located in FIG. 10. The expression that the line LN connecting the top portions 321t of the plurality of projections 321 “protrudes toward the first lens 20,” include a case in which the line LN forms one or more protruding shapes. In the first example illustrated in FIG. 11A, the line LN forms one protruding shape. The lower end C of the plurality of top portions 321t is located adjacent to the outer edge 302G of the second region 302.

In the second example illustrated in FIG. 11B, a line LN protrudes toward the −Z side as a whole, but a top portion 321t-2 is located on the +Z side relative to an imaginary straight line connecting a top portion 321t-1 and a top portion 321t-3. Therefore, a line LN1 consisting of a line connecting the top portion 321t-1 and the top portion 321t-2 and a line connecting the top portion 321t-2 and the top portion 321t-3 is recessed toward the +Z side when viewed locally or microscopically. As long as the line LN protrudes toward the −Z side when viewed as a whole or macroscopically, the line LN may include a portion recessed toward the +Z side when viewed locally or microscopically. As in the second example illustrated in FIG. 11B, in a case in which a middle one of three consecutive top portions 321t is located on the +Z side relative to an imaginary straight line connecting the other two top portions 321t of the three top portions 321t, the line LN connecting the top portions 321t of the plurality of projections 321 is regarded as forming two protruding shapes. A lowermost top portion C of the plurality of top portions 321t is located adjacent to the outer edge 302G of the second region 302.

In the third example illustrated in FIG. 11C, a line LN protrudes toward the −Z side as a whole, but a top portion 321t-5 is located on the +Z side relative to a top portion 321t-4. Therefore, a lowermost top portion C (top portion 321t-4) of a plurality of top portions 321t is located between the top portion 321t-5 and a top portion 321t-6. The lowermost top portion C of the plurality of top portions 321t need not be located adjacent to the outer edge 302G of the second region 302 as long as the lower end C is located between an end portion A and an end portion B.

As in the second example illustrated in FIG. 11B and the third example illustrated in FIG. 11C, according to the present embodiment, if a line LN protrudes toward the −Z side when viewed as a whole or macroscopically, the line LN can be regarded as “protruding toward the first lens 20.”

When only the optical functional portion 320 is focused and a line LN passing through top portions 321t of projections 321 is substantially straight in a cross section of the second lens 30 including the optical axis 30C of the second lens 30, the light incident surface 310 of the second lens 30 is regarded as a concave surface. FIG. 11D is an enlarged view illustrating a line connecting a plurality of top portions 321t according to a fourth example. In the example illustrated in FIG. 11D, a line LN is recessed toward the side opposite to the −Z side on which the first lens 20 is located.

A line LN connecting top portions 321t of a plurality of projections 321 may include a portion protruding toward the −Z side when viewed locally or microscopically as long as the line LN is recessed toward the +Z side when viewed as a whole or macroscopically. For example, the expression that a line LN connecting top portions 321t of a plurality of projections 321 is “recessed toward the side opposite to the first lens 20,” can indicate that the line LN has a shape including one or more recessed portions.

FIG. 9, FIG. 10, FIG. 11A, FIG. 11B, FIG. 11C, and FIG. 11D can be used as schematic diagrams each mainly illustrating a plurality of projections 321 included in the optical functional portion 320. In order to avoid complication of the drawings, the intervals, the number, and the like of the plurality of projections 321 included in the optical functional portion 320 are not necessarily the same among the drawings.

<Effects of Light-Emitting Module 100e>

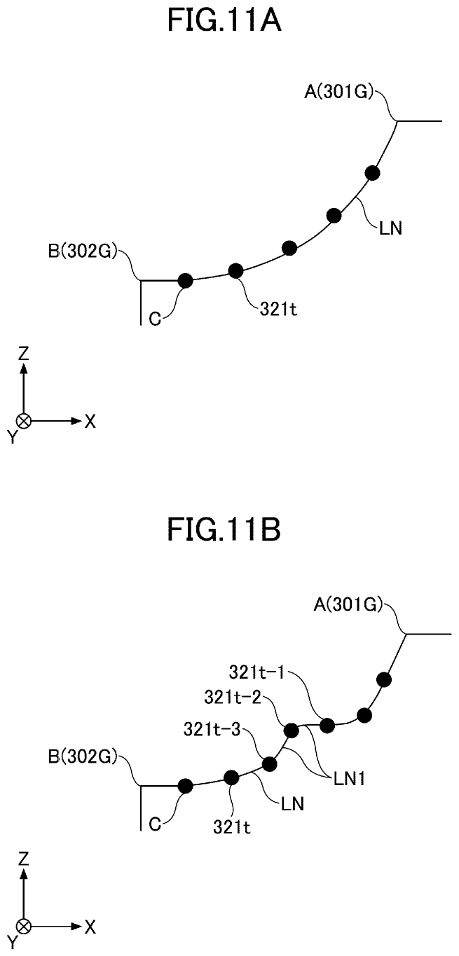

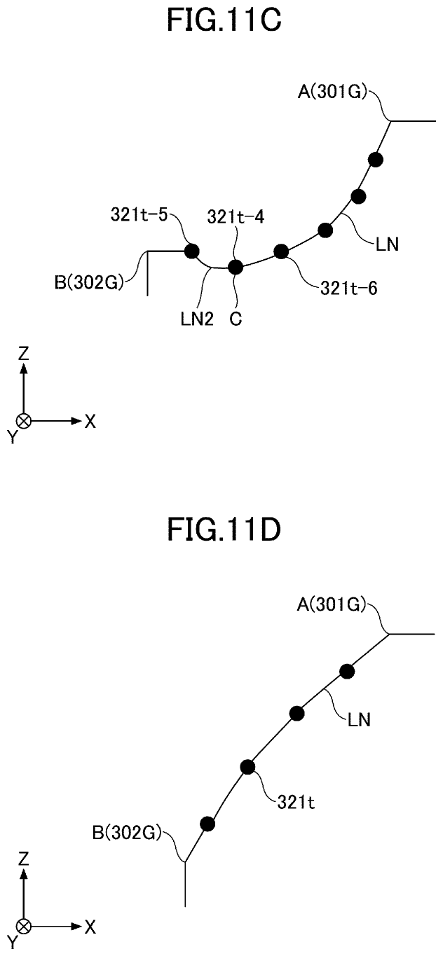

Effects of the light-emitting module 100e will be described with reference to FIG. 12 and FIG. 13. FIG. 12 is a diagram illustrating the illuminance of irradiation light when one of light-emitting parts 10 arranged at the four corners 17 of the light source 1 is caused to emit light in the light-emitting module 100e. FIG. 13 is a diagram illustrating the illuminance of irradiation light when one of the light-emitting parts arranged at four corners 17 of a light source is caused to emit light in a light-emitting module according to Comparative Example 3. The light-emitting module according to Comparative Example 3 differs from the light-emitting module 100e in that a second region 302 of a second lens 30 does not include an optical functional portion having a positive refractive power. In the example illustrated in FIG. 9, “one of the light-emitting parts 10 arranged at the four corners 17 of the light source 1” is a light-emitting part 10 disposed in the first row and the seventh column (at the upper right) in a top view. Light emitted from the light-emitting part 10 disposed at one of the corners 17 of the light source 1 is transmitted through the first support portion 21 of the first lens 20 illustrated in FIG. 10, and thus is less likely to be controlled. This light would tend to become stray light.

Each of FIG. 12 and FIG. 13 illustrates simulation results of the illuminance of irradiation light on an irradiation surface 200 when viewed from the +Z side. The irradiation surface 200 illustrated in FIG. 12 and FIG. 13 is in a range of 630 mm×840 mm and is positioned 300 mm away from each of the light-emitting modules. A region G1 is an illuminance distribution region of the irradiation light. A region G2 is an illuminance distribution region of stray light. In each of FIG. 12 and FIG. 13, a region with a color closer to white indicates that an illuminance of light irradiated onto the region is higher, and a region with a color closer to black indicates that an illuminance of light irradiated onto the region is lower. Meanwhile, a black region whose entire periphery is surrounded by a white region indicates that the illuminance in the black region is higher than the illuminance in the white region. Therefore, in the region G1, the illuminance in a black region surrounded by a white region is higher than the illuminance in the white region.

In the light-emitting module 100e according to the present embodiment illustrated in FIG. 12, the amount of stray light in the region G2 is smaller than that of the light-emitting module according to Comparative Example 3 illustrated in FIG. 13. The results indicate that, as compared to the light-emitting module according to Comparative Example 3, the light-emitting module 100e allows light emitted from the light-emitting part 10 disposed at the corner of the light source 1 and transmitted through the first support portion 21 illustrated in FIG. 10 to be controlled by the optical functional portion 320.

Table 1 below indicates a comparison between the luminous flux and the illuminance of irradiation light from the light-emitting module according to Comparative Example 3 and the luminous flux and the illuminance of irradiation light from the light-emitting module 100e according to the second embodiment under each of conditions 1 and 2. Further, Table 1 indicates the ratio of the luminous flux and the illuminance of the irradiation light from the light-emitting module 100e to the luminous flux and the illuminance of the irradiation light from the light-emitting module according to Comparative Example 3 when the luminous flux and the illuminance of the irradiation light from the light-emitting module according to Comparative Example 3 are each set to “1.0.” In condition 1, the illuminance was made substantially uniform on the entire irradiation surface by adjusting the positions and the light emission intensities of light-emitting parts to be turned on among sixty-three light-emitting parts, and the luminous flux of light emitted from the upper surface of a second light-transmissive member was calculated by a simulation for each of the light-emitting module according to the Comparative Example 3 and the light-emitting module 100e according to the second embodiment. The upper surface of the second light-transmissive member is, in detail, the upper surface of a second lens. In condition 2, one of the light-emitting parts arranged at the corners was caused to emit light and the maximum illuminance on the irradiation surface at this time was calculated by a simulation for each of the light-emitting module according to Comparative Example 3 and the light-emitting module 100e according to the second embodiment. In condition 2, the irradiation surface is in the range of 630 mm×840 mm and is positioned 300 mm away from each of the light-emitting modules.

TABLE 1

| | LIGHT-EMITTING | LIGHT-EMITTING |
|---|---|---|
| | MODULE | MODULE |
| | ACCORDING TO | ACCORDING TO |
| | COMPARATIVE | SECOND |
| | EXAMPLE 3 | EMBODIMENT |
| LUMINOUS | 1.0 | 1.2 |
| FLUX RATIO | | |
| (CONDITION 1) | | |
| MAXIMUM | 1.0 | 1.3 |
| ILLUMINANCE | | |
| RATIO | | |
| (CONDITION 2) | | |

As illustrated in Table 1, it was found that the irradiation light from the light-emitting module 100e according to the second embodiment had an illuminance higher than the illuminance of the irradiation light from the light-emitting module according to Comparative Example 3, and was efficiently guided toward the upper surface of the second light-transmissive member 3.

As described above, in the present embodiment, in a cross section of the second lens 30 including the optical axis 30C of the second lens 30, a line connecting top portions 321t of a plurality of projections 321 included in the optical functional portion 320 protrude toward the first lens 20. When the line LN including the top portions 321t of the projections 321 projects toward the first lens 20, the area of optical functional surfaces of the projections 321 of the optical functional portion 320 can be increased and the light controllability of the optical functional portion 320 can be improved, as compared to when the line LN including the top portions 321t of the projections 321 is recessed toward the side opposite to the first lens 20. The optical functional surfaces of the projections 321 refer to light-reflecting surfaces of the projections 321 that allow light L2, transmitted through the first support portion 21 of the first light-transmissive member 2 without being affected by the lens function of the first lens 20, to be guided in a direction toward the optical axis 30C of the second lens 30 and to contribute to light emitted from the light-emitting module 100e.

### Third Embodiment

Next, a light-emitting module according to a third embodiment will be described.

### <Configuration of Light-Emitting Module According to Third Embodiment>

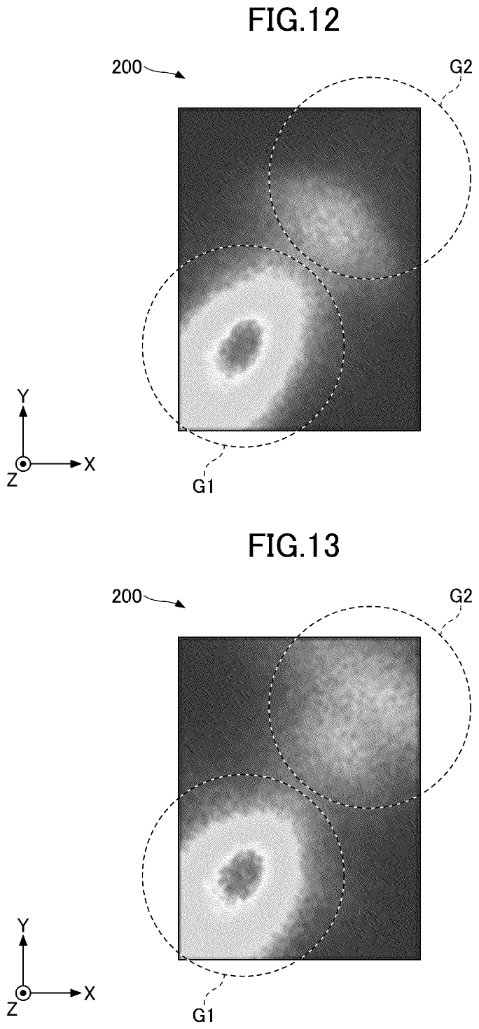

FIG. 14 is a schematic cross-sectional view of a light-emitting module 100g according to the third embodiment. The light-emitting module 100g according to the third embodiment differs from the light-emitting module 100e according to the second embodiment mainly in that a first support portion 21 of a first lens 20 has an annular projection 25 located at a light exit surface 21c of the first support portion 21 and outward of the first lens 20 in a top view.

In the example illustrated in FIG. 14, the annular projection 25 is a circular annular projection centered about an optical axis 20C of the first lens 20 in a top view. In the example illustrated in FIG. 14, the first support portion 21 of the first lens 20 has one annular projection 25. The annular projection 25 is adjacent to the outer edge of the first lens 20 in a top view. However, the annular projection 25 is not limited to one adjacent to the outer edge of the first lens 20 in a top view as long as the annular projection 25 is located outward of the first lens 20 in a top view. Further, the first support portion 21 of the first lens 20 may include a plurality of annular projections 25 centered about the optical axis 20C of the first lens 20 in a top view.

<Effects of Light-Emitting Module 100g>

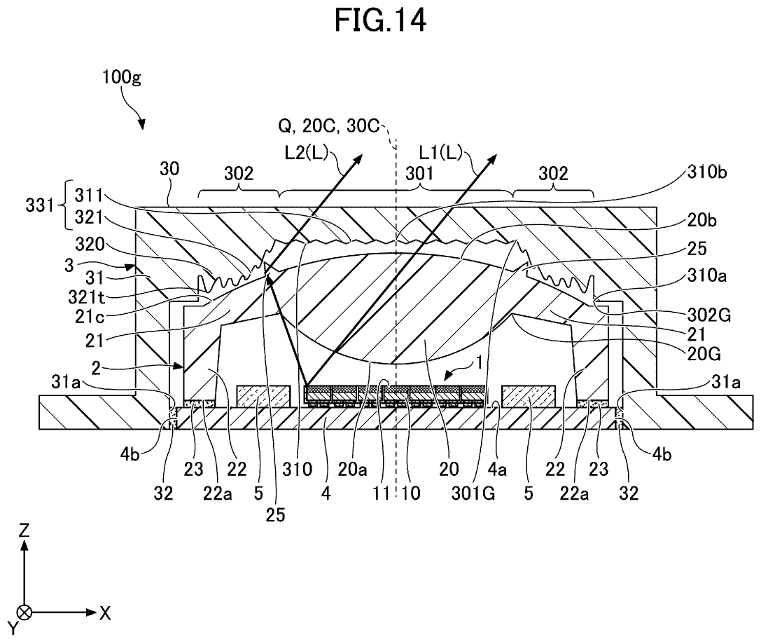

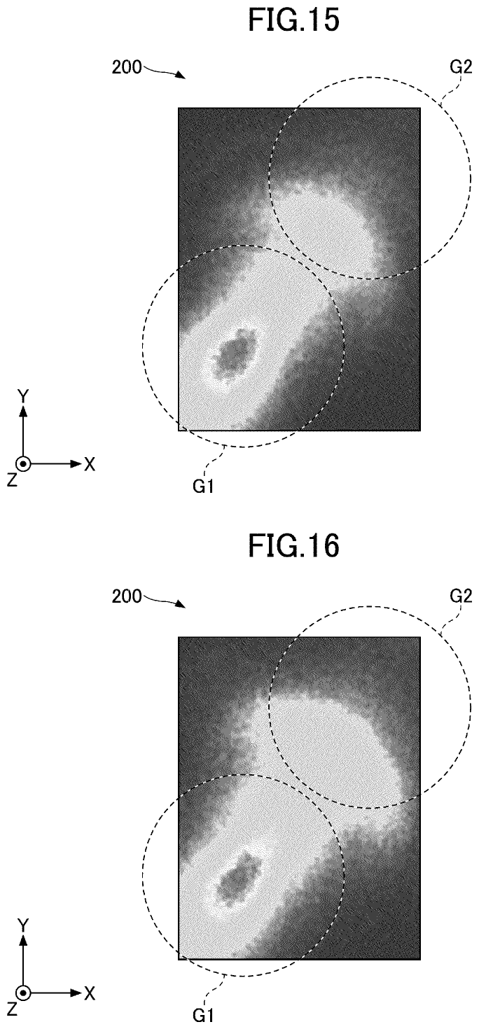

Effects of the light-emitting module 100g will be described with reference to FIG. 15 and FIG. 16. FIG. 15 is a diagram illustrating the illuminance of irradiation light when one of light-emitting parts 10 arranged at the four corners 17 of the light source 1 is caused to emit light in the light-emitting module 100g. FIG. 16 is a diagram illustrating the illuminance of irradiation light when one of the light-emitting parts 10 arranged at the corners 17 of the light source 1 are caused to emit light in the light-emitting module 100e according to the second embodiment. In simulations illustrated in FIG. 15 and FIG. 16, in order to facilitate understanding of the effects of the annular projection 25, light beams incident on the light incident surface 20a (located inward of the outer edge 20G) of the first lens 20 were excluded in each of the light-emitting module 100e and the light-emitting module 100g.

Each of FIG. 15 and FIG. 16 illustrates simulation results of the illuminance of irradiation light on the irradiation surface 200 when viewed from the +Z side. A region G1 is an illuminance distribution region of the irradiation light. A region G2 is an illuminance distribution region of stray light. In each of FIG. 15 and FIG. 16, a region with a color closer to white indicates that an illuminance of light irradiated onto the region is higher, and a region with a color closer to black indicates that an illuminance of light irradiated onto the region is lower. Meanwhile, a black region whose entire periphery is surrounded by a white region indicates that the illuminance in the black region is higher than the illuminance in the white region. Therefore, in the region G1, the illuminance in a black region surrounded by a white region is higher than the illuminance in the white region.

Stray light in a region G2 of the light-emitting module 100g according to the present embodiment illustrated in FIG. 15 was reduced as compared to stray light in a region G2 of the light-emitting module according to the second embodiment illustrated in FIG. 16. The results indicate that the light-emitting module 100g allows light emitted from the light-emitting part 10 disposed at one of the corners 17 of the light source 1 and transmitted through the first support portion 21 illustrated in FIG. 14 to be suitably controlled by the annular projection 25 of the second lens 30.

As described above, in the light-emitting module 100g according to the present embodiment, the first support portion 21 of the first lens 20 has at least one annular projection 25 located at the light exit surface 21c of the first support portion 21 and outward of the first lens 20 in a top view. Light emitted from the light source 1, passing through the first support portion 21, and then passing through the annular projection 25 is reflected at surface of the annular projection 25 toward the optical axis 30C of the second lens 30. Accordingly, the annular projection 25 can control light passing through the annular projection 25.

Further, for example, if the diameter of the first lens is increased in order to control light emitted from the corners or the like of the light source, the thickness of the first lens would be increased in accordance with the diameter, and the light-emitting module would become thick. In the present embodiment, light emitted from the corners 17 and the like of the light source 1 is controlled by the annular projection 25. Accordingly, the light controllability can be improved without increasing the thickness of the first lens 20. As a result, in the present embodiment, the light controllability can be improved without increasing the thickness of the light-emitting module 100g.

Further, for example, in a region of the first support portion 21 adjacent to the outer edge of the first lens 20, the controllability of light passing through the first support portion 21 may be reduced. In a region of the first support portion 21 adjacent to the outer edge of the first lens 20, the angle of a light beam emitted from the light source 1 with respect to the optical axis 20C is small. That is, a light beam emitted from the light source 1 incident on the light-reflecting surface of a projection 321 of the optical functional portion 320 at a small incident angle, and thus it is difficult to greatly bend the light beam by the light-reflecting surface of the projection 321. In the present embodiment, the annular projection 25 is adjacent to the outer edge of the first lens 20 in a top view. Accordingly, in the present embodiment, the controllability of light passing through a region adjacent to the outer edge of the first lens 20 can be improved.

### Fourth Embodiment

Next, a light-emitting module according to a fourth embodiment will be described.

### <Configuration of Light-Emitting Module According to Fourth Embodiment>

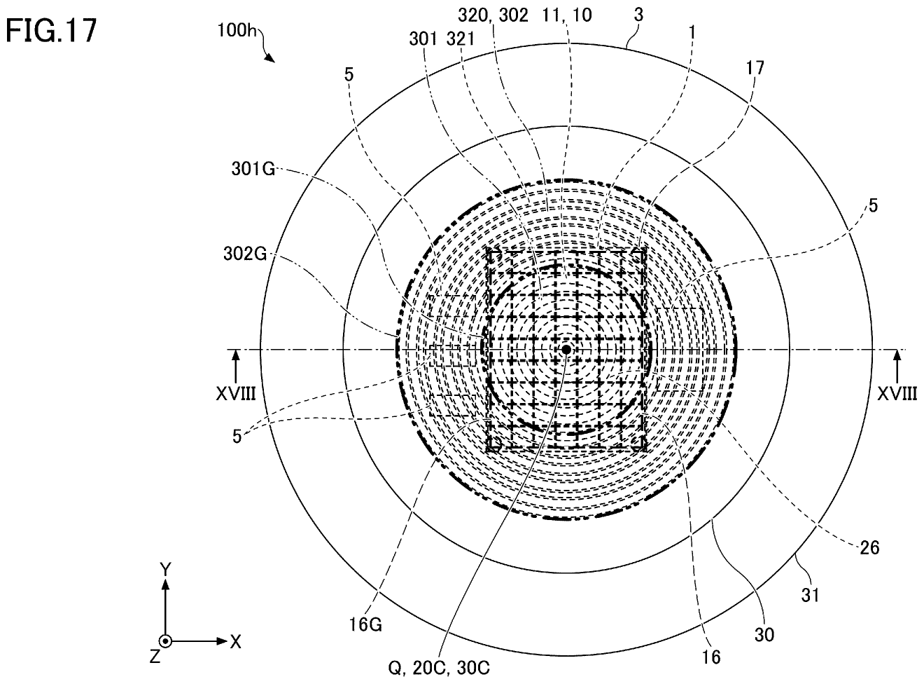

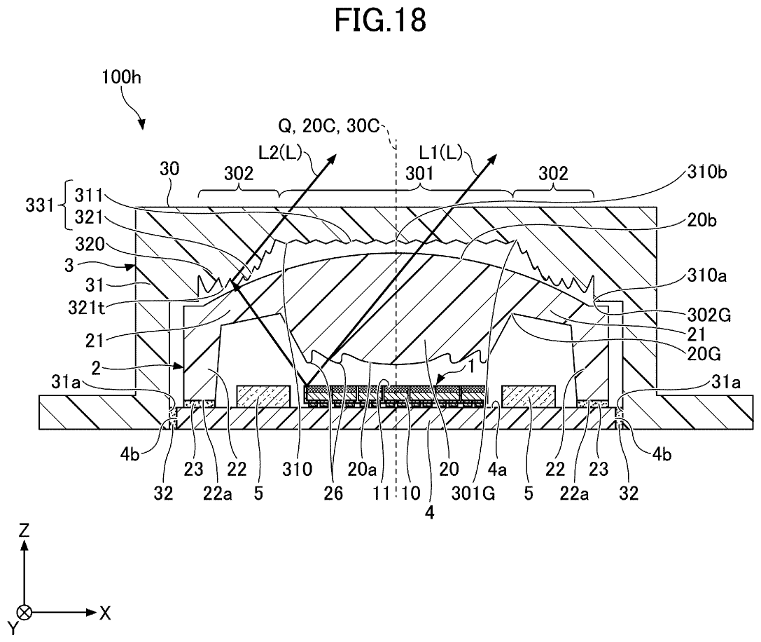

FIG. 17 is a schematic top view illustrating a light-emitting module 100h according to the fourth embodiment. FIG. 18 is a schematic cross-sectional view taken along line XVIII-XVIII of FIG. 17.

The light-emitting module 100h according to the fourth embodiment differs from the light-emitting module 100e according to the second embodiment mainly in that a light incident surface 20a of a first lens 20 of a first light-transmissive member 2 includes a plurality of annular projections 26.

Each of the plurality of annular projections 26 has a circular annular shape centered about an optical axis 20C of the first lens 20 in a top view. The plurality of annular projections 26 form, for example, a Fresnel lens surface. However, the plurality of annular projections 26 do not necessarily form a Fresnel lens surface. When the light-emitting module 100h includes the plurality of annular projections 26, the controllability of light emitted from the light source 1 and incident on the light incident surface 20a of the first lens 20 can be improved as compared to when the light-emitting module 100h does not include the plurality of annular projections 26.

FIG. 17 and FIG. 18 can be used as schematic views each mainly illustrating the plurality of annular projections 26. In order to avoid complication of the drawings, the positions, the intervals, the number, and the like of the plurality of annular projections 26 are not necessarily the same among the drawings.

### Fifth Embodiment

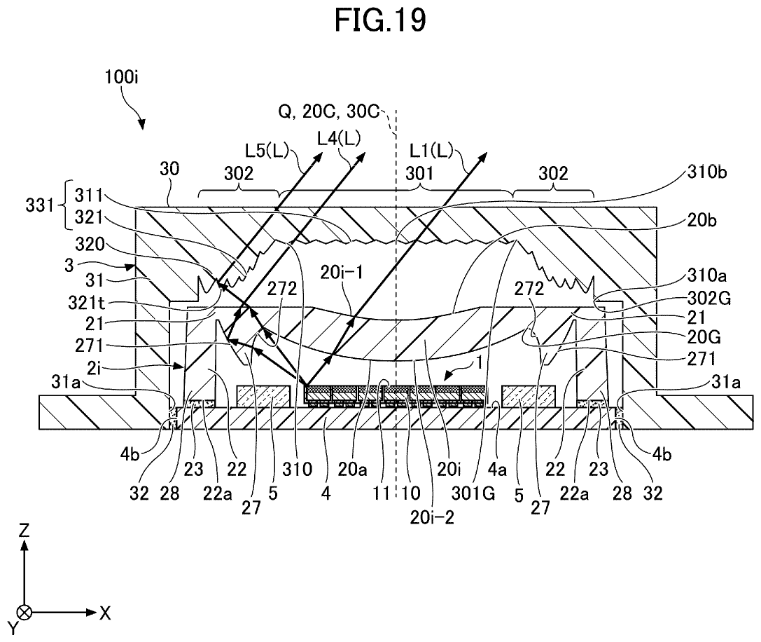

Next, a light-emitting module according to a fifth embodiment will be described with reference to FIG. 19 to FIG. 21.

### Configuration of Light-Emitting Module According to Fifth Embodiment

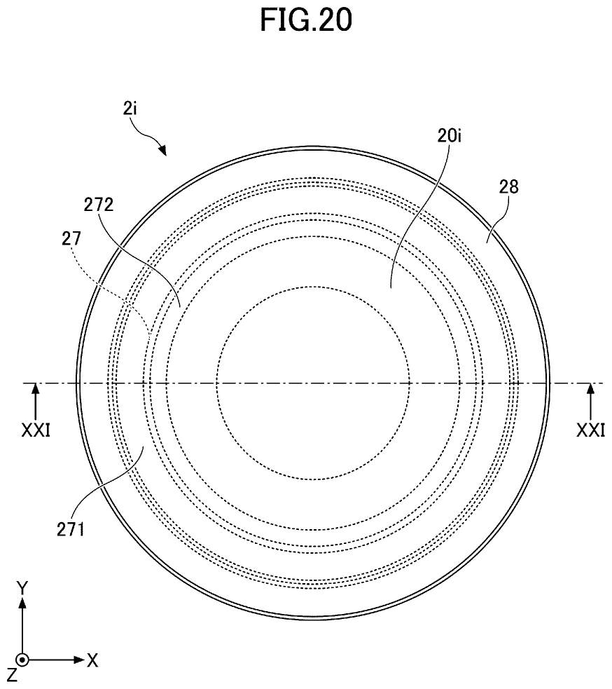

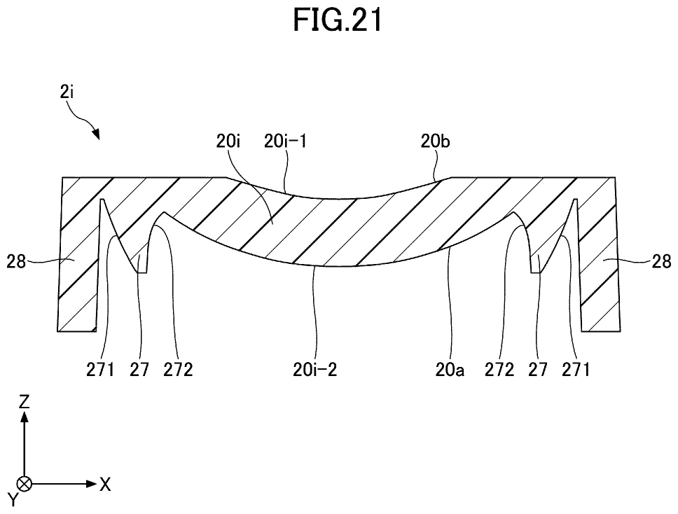

FIG. 19 is a schematic cross-sectional view illustrating a light-emitting module 100i according to the fifth embodiment. FIG. 19 illustrates a cross section of the light-emitting module 100i taken along a line corresponding to the line X-X of FIG. 9. FIG. 20 is a schematic top view illustrating a first light-transmissive member 2i of the light-emitting module 100i. FIG. 21 is a schematic cross-sectional view taken along line XXI-XXI of FIG. 20. In FIG. 19, light L1, light L4, and light L5 indicated by arrows represent portions of light L emitted from a light source 1 included in the light-emitting module 100i.

In the light-emitting module 100i according to the present embodiment, the first light-transmissive member 2i includes an annular light-incident convex portion 27 located outward of a first lens 20i in a top view and protruding toward the light source 1. An optical functional portion 320 includes a plurality of projections 321 located at a light incident surface 310 of a second lens 30. In a cross section of the second lens 30 including an optical axis 30C of the second lens 30, a line (LN; see FIG. 11A) connecting top portions 321t of the plurality of projections 321 protrudes toward the first lens 20i. The annular light-incident convex portion 27 has an annular light-reflecting surface 271 that reflects light emitted from the light source 1. The light-emitting module 100i differs from the light-emitting module 100 according to the first embodiment in the above configurations.

In the example illustrated in FIG. 19 to FIG. 21, the first lens 20i is supported by a third support portion 28 located outward of the first lens 20i in a top view. The annular light-incident convex portion 27 is located between the first lens 20i and the third support portion 28 in a top view.

A light exit surface 20b of the first lens 20i includes a concave surface 20i-1 recessed toward the light source 1. Further, a light incident surface 20a of the first lens 20i includes a convex surface 20i-2 facing the light source 1 and protruding toward the light source 1, and the first lens 20i has a positive refractive power. The concave surface 20i-1 has a substantially circular shape centered about the optical axis 20C of the first lens 20i in a top view. The convex surface 20i-2 has a substantially circular shape centered about the optical axis 20C of the first lens 20i in a top view. For example, the first lens 20i can have a positive refractive power by having the convex surface 20i-2 having a curvature greater than the curvature of the concave surface 20i-1.

The annular light-reflecting surface 271 reflects a large portion of incident light. For example, the annular light-reflecting surface 271 totally reflects a large portion of incident light. The annular light-reflecting surface 271 may include a reflecting film and reflect incident light by the reflecting film. As the reflecting film, a metal film, a dielectric multilayer film, or the like can be used. In the example illustrated in FIG. 19 to FIG. 21, the light-reflecting surface 271 includes a convex surface protruding toward the third support portion 28. However, the light-reflecting surface 271 may include a flat surface.

The annular light-incident convex portion 27 has an inner concave surface 272 located inward of the annular light-reflecting surface 271 in a top view and recessed toward the annular light-reflecting surface 271. The inner concave surface 272 overlaps the optical functional portion 320 or is located inward of the optical functional portion 320 in a top view. In the example illustrated in FIG. 19 to FIG. 21, the inner concave surface 272 overlaps the optical functional portion 320 in a top view. The inner concave surface 272 refracts light emitted from the light source 1 and incident on the inner concave surface 272, and guides the light to the optical functional portion 320.

The first light-transmissive member 2i includes at least one of: a resin material, such as a polycarbonate resin, an acrylic resin, a silicone resin, or an epoxy resin; or a glass material, which have light transmissivity with respect to light emitted from the light source 1. The first lens 20i, the annular light-incident convex portion 27, and the third support portion 28 are formed of the same material and connected to one another as a single body. At least one of the first lens 20i, the annular light-incident convex portion 27, the third support portion 28 may be formed of a different material.

<Effects of Light-Emitting Module 100i>

In the present embodiment, the light-emitting module 100i includes the first light-transmissive member 2i. Thus, of light L emitted from the light source 1, light L4 traveling toward the second support portion 31 is reflected by the light-reflecting surface 271 of the annular light-incident convex portion 27 toward the optical axis 20C of the first lens 20i. With this configuration, of light L traveling toward the second support portion 31, light passing through the second support portion 31 and emitted from the light-emitting module can be reduced, that is, light that becomes stray light can be reduced and the light (light L4) can contribute to light emitted from the light-emitting module 100i. As a result, the light extraction efficiency of the light-emitting module 100i can be increased.

Further, in the present embodiment, the light L4 incident on the annular light-incident convex portion 27 is reflected by the light-reflecting surface 271 toward the optical axis 20C of the first lens 20i. Thus, the traveling direction of the light L4 can be greatly changed. In the present embodiment, by greatly changing the traveling direction of the light L4 incident on the annular light-incident convex portion 27, the amount of light L that cannot be controlled by the first light-transmissive member 2 can be reduced and thus stray light can be reduced. As a result, the light extraction efficiency of the light-emitting module 100i can be increased.

The light exit surface 20b of the first lens 20i can include the concave surface 20i-1 recessed toward the light source 1. When the light exit surface 20b of the first lens 20i includes the concave surface 20i-1, the possibility that light L1 incident on the first lens 20i is totally reflected by the light exit surface 20b of the first lens 20i can be reduced. Accordingly, in the present embodiment, the amount of light L that is totally reflected by the light exit surface 20b of the first lens 20i and does not contribute to light emitted from the light-emitting module 100i can be reduced. As a result, the light extraction efficiency of the light-emitting module 100i can be increased.

The light incident surface 20a of the first lens 20i can include the convex surface 20i-2 facing the light source 1 and protruding toward the light source 1, and can have a positive refractive power. When the first lens 20i has a positive refractive power, the traveling direction of light L incident on the first lens 20i from the light source 1 can be changed. For example, in the light-emitting module 100i, in the distribution of light passing through the center Q of the light source 1 (in other words, the center of the light-emitting region 16) and a corner 17 of the light-emitting region 16, a peak angle at which the luminous intensity of light emitted from a light-emitting part 10 disposed at the corner 17 of the light-emitting region 16 reaches its peak can be increased. As a result, the light-emitting module 100i can emit light with a wide angle distribution.

The annular light-incident convex portion 27 can have the inner concave surface 272 located inward of the annular light-reflecting surface 271 and recessed toward the light-reflecting surface 271 in a top view. The inner concave surface 272 can overlap the optical functional portion 320 or can be located inward of the optical functional portion 320 in a top view. Accordingly, in the present embodiment, of light L emitted from the light source 1 and passing through the annular light-incident convex portion 27, light L5 that is not incident on the light-reflecting surface 271 of the annular light-incident convex portion 27 can be guided to the optical functional portion 320 by the inner concave surface 272 of the annular light-incident convex portion 27. As a result, of the light L, the light L5 that is not incident on the light-reflecting surface 271 of the annular light-incident convex portion 27 can contribute to light emitted from the light-emitting module 100i by the function of the optical functional portion 320, and thus the light extraction efficiency of the light-emitting module 100i can be improved.

Although embodiments have been described in detail above, the above-described embodiments are non-limiting examples, and various modifications and substitutions can be made to the above-described embodiments without departing from the scope described in the claims.

The numbers such as ordinal numbers and quantities used in the description of the embodiments are all exemplified to specifically describe the technique of the present disclosure, and the present disclosure is not limited to the exemplified numbers. In addition, the connection relationship between the components is illustrated for specifically describing the technique of the present disclosure, and the connection relationship for implementing the functions of the present disclosure is not limited thereto.

The light-emitting modules according to the present disclosure have high light extraction efficiency. Therefore, the light-emitting modules according to the present disclosure can be suitably used for lighting, camera flashes, vehicle headlights, and the like. However, the light-emitting modules according to the present disclosure are not limited to these applications.

According to one embodiment of the present disclosure, a light-emitting module having high light extraction efficiency can be provided.

What is claimed is:

1. A light-emitting module comprising:
a light source;
a first light-transmissive member comprising a first lens disposed above the light source; and
a second light-transmissive member comprising a second lens disposed above the first light-transmissive member, wherein:
the light source, the first lens, and the second lens are spaced apart from one another,
a light incident surface of the second lens comprises:
a first region overlapping an optical axis of the second lens and overlapping at least the light source, in a top view, and
a second region surrounding the first region in the top view,
the second lens comprises, in the second region, at least one optical functional portion having a positive refractive power, and
the refractive power of the at least one optical functional portion is greater than a refractive power of the second lens in the first region.

2. The light-emitting module according to claim 1, wherein the light incident surface of the second lens is a concave surface.

3. The light-emitting module according to claim 1, wherein:
the optical functional portion is located at the light incident surface of the second lens, and
the optical functional portion comprises a plurality of projections.

4. The light-emitting module according to claim 1, wherein
the first region of the light incident surface of the second lens comprises a plurality of first projections
the optical functional portion comprises plurality of second projections, and
in a cross section of the second lens including the optical axis of the second lens, a first angle at which two lines forming one of the plurality of second projections of the optical functional portion meet is smaller than a second angle at which two lines forming one of the plurality of first projections of the first region meet.

5. The light-emitting module according to claim 4, wherein, in the cross section of the second lens including the optical axis of the second lens, the second angle is identical among the plurality of first projections.

6. The light-emitting module according to claim 1, wherein the at least one optical functional portion includes a plurality of optical functional portions arranged radially around the optical axis of the second lens in the top view.

7. The light-emitting module according to claim 1, wherein:
the light source has a light-emitting region having a rectangular shape in the top view, and
the optical functional portion overlaps corners of the light-emitting region in the top view.

8. The light-emitting module according to claim 1, further comprising:
an electronic component disposed at a position overlapping the optical functional portion in the top view.

9. The light-emitting module according to claim 1, wherein a curvature of a light incident surface of the first lens is greater than a curvature of a light exit surface of the first lens.

10. The light-emitting module according to claim 1, wherein an outer edge of the first region is located outward of an outer edge of the first lens in the top view.

11. The light-emitting module according to claim 1, wherein:
the first light-transmissive member comprises a first support portion that supports the first lens, and
the optical functional portion overlaps at least a portion of the first support portion in the top view.

12. The light-emitting module according to claim 1, wherein:
the light source includes a plurality of light-emitting parts, and
each of the plurality of light-emitting parts is configured to be individually driven to emit light.

13. A flash comprising the light-emitting module according to claim 1.

14. The light-emitting module according to claim 1, wherein:
the optical functional portion comprises a plurality of projections located at the light incident surface of the second lens, and
in a cross section of the second lens including the optical axis of the second lens, a line connecting respective top portions of the plurality of projections protrudes toward the first lens.

15. The light-emitting module according to claim 1, wherein:
the optical functional portion comprises a plurality of projections located at the light incident surface of the second lens, and
projection intervals between adjacent projections of the plurality of projections are identical to each other.

16. The light-emitting module according to claim 1, wherein:
the first light-transmissive member comprises a first support portion that supports the first lens, and
the first support portion comprises an annular projection located at a light exit surface of the first support portion and outward of the first lens in the top view.

17. The light-emitting module according to claim 16, wherein the annular projection is adjacent to an outer edge of the first lens in the top view.

18. The light-emitting module according to claim 1, wherein:
the first light-transmissive member comprises an annular light incident convex portion located outward of the first lens in the top view and protruding toward the light source,
the optical functional portion comprises a plurality of projections located at the light incident surface of the second lens,
in a cross section of the second lens including the optical axis of the second lens, a line connecting respective top portions of the plurality of projections protrudes toward the first lens, and
the annular light incident convex portion has an annular light-reflecting surface configured to reflect light from the light source.

19. The light-emitting module according to claim 18, wherein a light exit surface of the first lens includes a concave surface recessed toward the light source.

20. The light-emitting module according to claim 18, wherein:
a light incident surface of the first lens includes a convex surface facing the light source and protruding toward the light source, and
the first lens has a positive refractive power.

21. The light-emitting module according to claim 18, wherein:
the annular light incident convex portion has an inner concave surface located inward of the annular light-reflecting surface in the top view and recessed toward the light-reflecting surface, and
the inner concave surface overlaps the optical functional portion in the top view or is located inward of the optical functional portion in the top view.
